(19) United States
(12) Patent Application Publication
(10) Pub. No.: US 2026/0282208 A1
(43) Pub. Date: Sep. 17, 2026

(54) WIRING BOARD AND HEAD-MOUNTED DISPLAY

(71) Applicant: DAI NIPPON PRINTING CO., LTD., Tokyo-to (JP)

(72) Inventors: Seiji TAKE, Tokyo-to (JP); Kazuki KINOSHITA, Tokyo-to (JP); Keita IIMURA, Tokyo-to (JP); Yuya AIDA, Tokyo-to (JP); Masao FUKUSHIMA, Tokyo-to (JP)

(73) Assignee: DAI NIPPON PRINTING CO., LTD., Tokyo-to (JP)

(21) Appl. No.: 19/162,683

(22) PCT Filed: Feb. 22, 2024
(86) PCT No.: PCT/JP2024/006661

§ 371 Date: Sep. 5, 2025

(30) Foreign Application Priority Data
Mar. 7, 2023 (JP) 2023-034721

(51) Int. Cl. H05K 1/02

(52) U.S. Cl. CPC H05K 1/0242; H05K 1/0224

(57) ABSTRACT

A wiring board includes a substrate that is transparent, and a mesh wiring layer that is disposed on the substrate. The wiring board has an electromagnetic wave transceiver function. The mesh wiring layer is configured to be a transceiver portion for an electromagnetic wave and includes a wiring line. A planar shape of the wiring line has multiple curves that are connected to each other. The curves are arcs or elliptical arcs.

### TECHNICAL FIELD

An embodiment of the present disclosure relates to a wiring board and a head-mounted display.

### BACKGROUND ART

Mobile terminal devices such as a smart phone, a tablet, and smart glasses (for example, AR and MR) are currently being developed for higher functionality, smaller sizes, thinner bodies, and lighter weights. These mobile terminal devices use multiple communication bands. For this reason, multiple antennas that support the communication bands are needed. For example, a mobile terminal device includes multiple antennas such as a telephone antenna, a WiFi (Wireless Fidelity) antenna, a 3G (Generation) antenna, a 4G (Generation) antenna, a 5G (Generation) antenna, a LTE (Long Term Evolution) antenna, a Bluetooth (registered trademark) antenna, and a NFC (Near Field Communication) antenna. However, since the mobile terminal device has a smaller size, a space in which the antennas are installed is limited, and the degree of freedom of antenna design reduces. Since the antennas are contained in the limited space, radio wave sensitivity is not necessarily satisfactory.

For this reason, a film antenna that can be installed in a display region of a mobile terminal device or transparent regions of smart glasses is developed. The film antenna is a transparent antenna that is obtained by forming an antenna pattern on a transparent base material. The antenna pattern is formed by using a conductive mesh layer in the form of mesh. The conductive mesh layer includes a conductive portion that serves as a formation portion for an opaque conductive layer and a large number of opening portions that serve as non-formation portions.

### CITATION LIST

### Patent Literature

Patent Literature 1: Japanese Unexamined Patent Application Publication No. 2011-66610

Patent Literature 2: Japanese Patent No. 5,636,735

Patent Literature 3: Japanese Patent No. 5,695,947

An existing film antenna has a region in which a conductive mesh layer (an antenna pattern) is formed on a transparent base material. In the case where a wiring line in the conductive mesh layer is disposed in the form of a regular lattice, a beam of light depending on the direction of the wiring line can be observed when a point light source is observed. As for, for example, the mobile terminal device, in the case where the beam of light is thus observed, there is a possibility that the visibility of an image reduces.

It is thought that the periodicity of the wiring line is eliminated to remove the beam of light. In the case where the periodicity of the wiring line is eliminated, however, there is a possibility that the directions of wiring lines are changed into various directions, and flicker due to light reflection occurs.

It is an object of the present embodiment to provide a wiring board and a head-mounted display that inhibit visibility from reducing due to a beam of light and that enable flicker due to reflected light to be reduced.

### SUMMARY OF INVENTION

According to a first aspect of the present disclosure, a wiring board includes a substrate that is transparent, and a mesh wiring layer that is disposed on the substrate. The wiring board has an electromagnetic wave transceiver function. The mesh wiring layer is configured to be a transceiver portion for an electromagnetic wave and includes a wiring line. A planar shape of the wiring line has multiple curves that are connected to each other. The curves are arcs or elliptical arcs.

According to a second aspect of the present disclosure, an aperture ratio of the mesh wiring layer may be 94% or more, as for the wiring board according to the first aspect described above,

According to a third aspect of the present disclosure, an opening portion may be formed by being surrounded by the wiring line, as for the wiring line that surrounds the opening portion, a shape obtained by connecting end portions of chords of the multiple curves may be a polygonal shape, the wiring line may have a shape obtained by connecting multiple arcs that are cut at a central angle of 160° or more and 200° or less to each other, a side of the polygonal shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above or the second aspect described above.

According to a fourth aspect of the present disclosure, a plurality of the opening portions may be formed, and a corner portion of the polygonal shape may be irregularly arranged, as for the wiring board according to the third aspect described above.

According to a fifth aspect of the present disclosure, an opening portion may be formed by being surrounded by the wiring line, as for the wiring line that surrounds the opening portion, a shape obtained by connecting end portions of chords of the multiple curves may be a square shape, the wiring line may have a shape obtained by connecting multiple arcs that are cut at a central angle of 160° or more and 200° or less to each other, a side of the square shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above.

According to a sixth aspect of the present disclosure, an opening portion may be formed by being surrounded by the wiring line, as for the wiring line that surrounds the opening portion, a shape obtained by connecting end portions of chords of the multiple curves may be a square shape, the wiring line may have a shape obtained by connecting multiple arcs that are cut at a central angle of 80° or more and 100° or less to each other, a side of the square shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above.

According to a seventh aspect of the present disclosure, the curves may be arcs that are cut at a central angle of 180°, as for the wiring board according to any one of the first aspect described above to the fifth aspect described above or the curves may be arcs that are cut at a central angle of 90°, as for the wiring board according to the first aspect described above or the sixth aspect described above.

According to an eighth aspect of the present disclosure, an opening portion may be formed by being surrounded by the wiring line, as for the wiring line that surrounds the opening portion, a shape obtained by connecting end portions of chords of the multiple curves may be a rhomboidal shape, the wiring line may have a shape obtained by connecting multiple arcs that are cut at a central angle of 160° or more and 200° or less to each other, a side of the rhomboidal shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above.

According to a ninth aspect of the present disclosure, an opening portion may be formed by being surrounded by the wiring line, as for the wiring line that surrounds the opening portion, a shape obtained by connecting end portions of chords of the multiple curves may be a regular hexagonal shape, the wiring line may have a shape obtained by connecting multiple arcs that are cut at a central angle of 160° or more and 200° or less to each other, a side of the regular hexagonal shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above.

According to a tenth aspect of the present disclosure, an opening portion may be formed by being surrounded by the wiring line, as for the wiring line that surrounds the opening portion, a shape obtained by connecting end portions of chords of the multiple curves may be a polygonal shape, the wiring line may have a shape obtained by connecting multiple arcs that are cut at a central angle of 80° or more and 100° or less to each other, a side of the polygonal shape may be formed by 2N (N is a natural number of 1 or more) chords, and a distance from an M-th dividing point to an M-th connection point may be 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords, as for the wiring board according to the first aspect described above.

According to an eleventh aspect of the present disclosure, the polygonal shape may be a rhomboidal shape or a hexagonal shape, as for the wiring board according to the tenth aspect described above.

According to a twelfth aspect of the present disclosure, N may be 1, as for the wiring board according to any one of the first aspect described above to the eleventh aspect described above.

According to a thirteenth aspect of the present disclosure, the wiring board may have a radio wave transceiver function at a frequency of 1 GHz or more, as for the wiring board according to any one of the first aspect described above to the twelfth aspect described above.

According to a fourteenth aspect of the present disclosure, the mesh wiring layer may have an electromagnetic wave shielding function, as for the wiring board according to any one of the first aspect described above to the thirteenth aspect described above.

According to a fifteenth aspect of the present disclosure, an increase in a resistance value of the mesh wiring layer may be 10% or less when an operation in which the wiring board is bent at 180° around a cylinder having a diameter of 1 mm and is subsequently stretched is repeated 10 times, as for the wiring board according to any one of the first aspect described above to the fourteenth aspect described above.

According to a sixteenth aspect of the present disclosure, a dummy wiring layer that is electrically separated from the mesh wiring layer may be provided around the mesh wiring layer, as for the wiring board according to any one of the first aspect described above to the fifteenth aspect described above.

According to a seventeenth aspect of the present disclosure, a plurality of the dummy wiring layers may be provided, and aperture ratios of the mesh wiring layer and the dummy wiring layers may increase stepwise in order from the mesh wiring layer to the dummy wiring layers far from the mesh wiring layer, as for the wiring board according to any one of the first aspect described above to the sixteenth aspect described above.

An eighteenth aspect of the present disclosure, a head-mounted display includes a frame, and a display device that is mounted on the frame and that is transparent. The display device includes a first base material, the wiring board according to any one of the first aspect described above to the seventeenth aspect described above that is provided on the first base material, and a display unit that is provided between the first base material and the wiring board.

According to an embodiment of the present disclosure, visibility can be inhibited from reducing due to a beam of light, and flicker due to reflected light can be reduced.

### BRIEF DESCRIPTION OF DRAWINGS

FIG. 1 is a perspective view of a head-mounted display according to an embodiment.

FIG. 2 is a front view (viewed in a II direction in FIG. 1) of the head-mounted display according to an embodiment.

FIG. 3 is a sectional view (a sectional view taken along a line III-III in FIG. 2) of a display device of the head-mounted display according to an embodiment.

FIG. 4 is a plan view of a wiring board according to an embodiment.

FIG. 5 is an enlarged plan view of a mesh wiring layer of the wiring board according to an embodiment.

FIG. 6 is a sectional view (a sectional view taken along a line VI-VI in FIG. 5) of the wiring board according to an embodiment.

FIG. 7 is a sectional view (a sectional view taken along a line VII-VII in FIG. 5) of the wiring board according to an embodiment.

FIG. 8A is a sectional view for a method of manufacturing the wiring board according to an embodiment.

FIG. 8B is a sectional view for the method of manufacturing the wiring board according to an embodiment.

FIG. 8C is a sectional view for the method of manufacturing the wiring board according to an embodiment.

FIG. 8D is a sectional view for the method of manufacturing the wiring board according to an embodiment.

FIG. 8E is a sectional view for the method of manufacturing the wiring board according to an embodiment.

FIG. 8F is a sectional view for the method of manufacturing the wiring board according to an embodiment.

FIG. 9 is an enlarged plan view of a wiring board according to a first modification.

FIG. 10A is an enlarged plan view of a wiring board according to a second modification.

FIG. 10B is an enlarged plan view of another example of the wiring board according to the second modification.

FIG. 11 is an enlarged plan view of a wiring board according to a third modification.

FIG. 12A is an enlarged plan view of a wiring board according to a fourth modification.

FIG. 12B is an enlarged plan view of another example of the wiring board according to the fourth modification.

FIG. 13 is an enlarged plan view of a wiring board according to a fifth modification.

FIG. 14 is an enlarged plan view of another example of the wiring board according to the fifth modification.

FIG. 15 is an enlarged plan view of another example of the wiring board according to the fifth modification.

FIG. 16 is a plan view of a wiring board of a sixth modification.

FIG. 17 is an enlarged plan view of the wiring board according to the sixth modification.

FIG. 18 is a plan view of a wiring board of a seventh modification.

FIG. 19 is an enlarged plan view of the wiring board according to the seventh modification.

### DESCRIPTION OF EMBODIMENTS

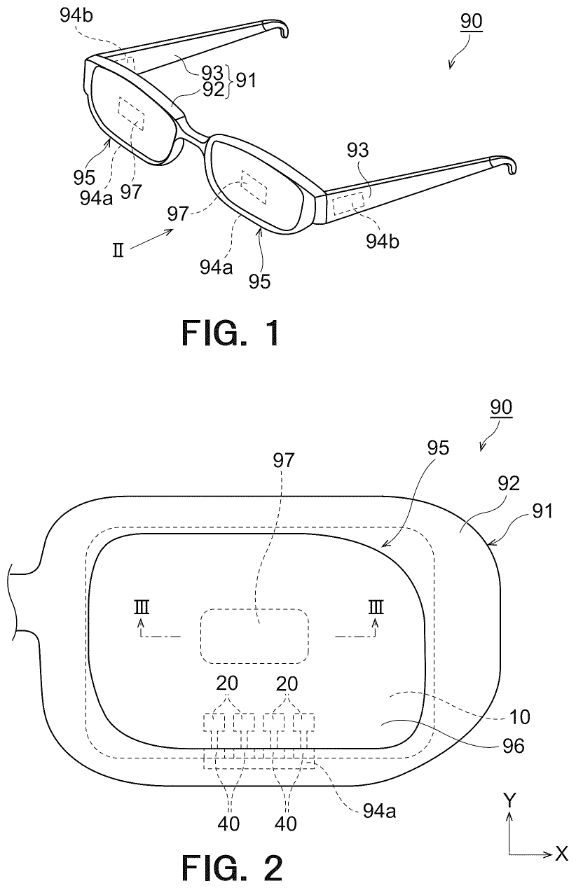

An embodiment will now be described with reference to FIG. 1 to FIG. 8F. FIG. 1 to FIG. 8F illustrate the present embodiment.

The figures described below are schematically illustrated. For this reason, the sizes and shapes of components are appropriately exaggerated to make understanding easy. Modifications can be appropriately made without departing from a technical idea. In the figures described below, like components are designated by using like reference signs, and a detailed description is omitted in some cases. Material names and numerals such as dimensions of members described in the present specification are examples according to the embodiment, are not limited thereto, and can be appropriately selected and used. In the present specification, words such as parallel, perpendicular, and vertical that specify shapes or geometrical conditions can be interpreted as substantially the same meaning in addition to strict meaning.

In the embodiment described below, an “X-direction” is a direction parallel with a side of a substrate. A “Y-direction” is a direction perpendicular to the X-direction and parallel with another side of the substrate. A “Z-direction” is a direction perpendicular to both of the X-direction and the Y-direction and parallel with the thickness direction of the substrate. A “front surface” means a surface in a positive Z-direction that faces a wearer. A “back surface” means a surface in a negative Z-direction that is opposite the surface that faces the wearer.

The structure of a head-mounted display (simply referred to below as a HMD) according to the present embodiment will now be described with reference to FIG. 1 to FIG. 3. The HMD according to the present embodiment is a transparent (see-through) HMD.

As illustrated in FIG. 1, a HMD 90 according to the present embodiment includes a frame 91 and display devices 95 that are mounted on the frame 91 and that are transparent. According to the present embodiment, the HMD 90 includes the display device 95 for the right-hand eye and the display device 95 for the left-hand eye and is a so-called eyeglass HMD. The display device 95 for the right-hand eye and the display device 95 for the left-hand eye have substantially the same structure. The display devices 95 are synchronized with each other and are configured to display the same image on the left and right sides or are configured to display corresponding images on the left and right sides. The two display devices 95 may be capable of being individually controlled, and the two display devices 95 may display different images. The HMD 90 may be a so-called goggles HMD that includes a single display device 95.

The frame 91 of the HMD 90 includes a rim 92 and a pair of temples 93 coupled with the rim 92. The display devices 95 are fitted into the rim 92. According to the present embodiment, wireless communication circuits 94a of the HMD 90 are provided on the rim 92.

Control units 94b for controlling the display devices 95 are provided on the pair of temples 93. The control units 94b may include an image display unit (not illustrated) that generates image light. According to the present embodiment, the control units 94b are disposed on the respective temples 93. The control unit 94b that is disposed on the temple 93 on the right-hand side controls the display device 95 for the right-hand eye, and the control unit 94b that is disposed on the temple 93 on the left-hand side controls the display device 95 for the left-hand eye.

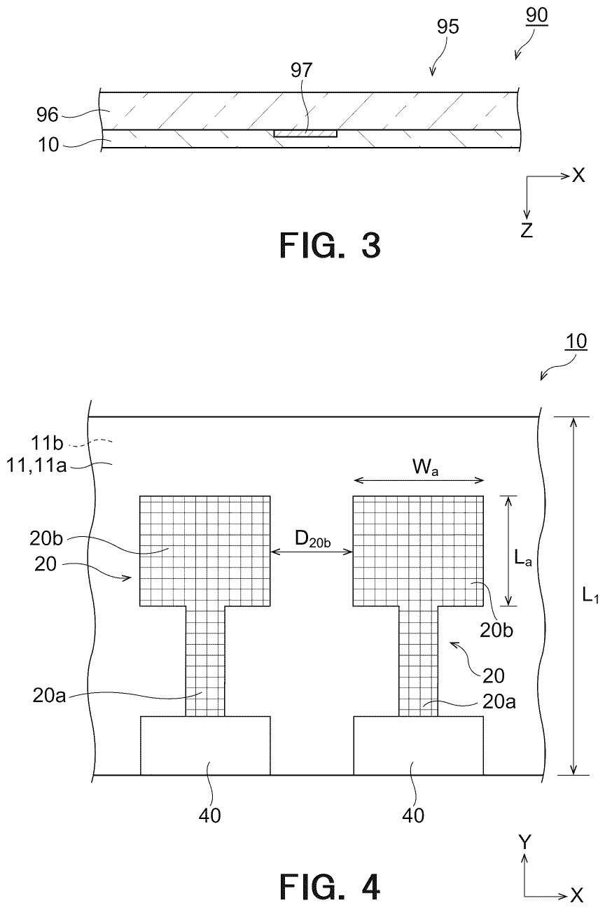

The display devices 95 will now be described. As illustrated in FIG. 2 and FIG. 3, each display device 95 includes a first base material 96, a wiring board 10 that is provided on the first base material 96, and a display unit 97 that is provided between the first base material 96 and the wiring board 10. According to the present embodiment, the wiring board 10 covers the entire region of the first base material 96. The wiring board 10 may cover only a portion of the first base material 96 although this is not illustrated.

The first base material 96 may be composed of a material that is transparent in a visible light region. A glass base material, for example, may be used as the first base material 96. According to the present embodiment, when the wearer wears the HMD 90, the first base material 96 is distal to the wearer, and the wiring board 10 is proximal to the wearer. That is, when the wearer wears the HMD 90, the wiring board 10 is located between the first base material 96 and the wearer. Consequently, for example, even in the case where the HMD 90 comes into contact with a surrounding structure or another person when the wearer wears the HMD 90, the wiring board 10 can be inhibited from coming into contact with, for example, the surrounding structure. For this reason, first direction wiring lines 21 and second direction wiring lines 22 of mesh wiring layers 20 of the wiring board 10 described later can be inhibited from being disconnected due to contact with, for example, the surrounding structure. When the wearer wears the HMD 90, the first base material 96 may be proximal to the wearer, and the wiring board 10 may be distal to the wearer.

Each display device 95 may be a display device that projects an image by using a prism or a hologram or may be a display device that uses, for example, a transparent liquid-crystal display.

In the case where each display device is the display device that projects the image, the display unit 97 of the display device 95 may include a one-way mirror. The one-way mirror is a member that superimposes ambient light in front of the display device 95 and the image light from the image display unit (not illustrated) that generates the image light on each other. In the case where each display device 95 is the display device that uses, for example, the transparent liquid-crystal display, the one-way mirror is not needed. The display unit 97 is configured such that a display region for the image is transparent when the image is not displayed and enables the wearer to visually recognize surroundings by using light that passes through the display unit 97. The wearer can visually recognize a virtual image (an image) that is formed by the image light while visually recognizing the surroundings. In an illustrated example, the display unit 97 is provided so as to overlap a substantially central portion of the first base material 96 in front view (see FIG. 2). However, this is not a limitation, and the display unit 97 may be provided so as to overlap a freely selected region of the first base material 96 in front view. The display unit 97 and the wiring board 10 may be disposed so as to overlap such that the positions thereof do not interfere with each other or may be disposed so as not to overlap.

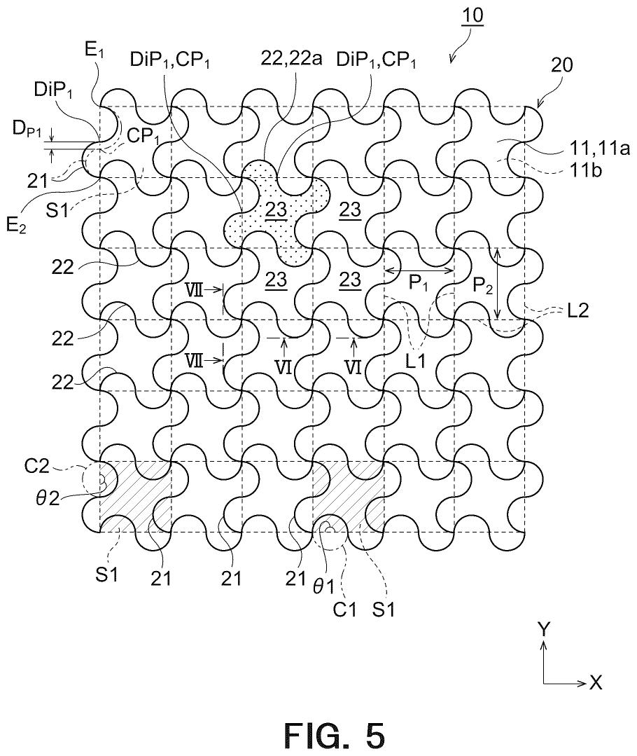

The structure of the wiring board will now be described with reference to FIG. 4 to FIG. 7. FIG. 4 to FIG. 7 illustrate the wiring board according to the present embodiment.

An example of the wiring board 10 according to the present embodiment is a substrate that is used for the HMD 90 (see FIG. 1 to FIG. 3) described above. For example, the wiring board 10 may be used for a mobile terminal device such as a smart phone or a tablet.

The wiring board 10 can transmit and receive a radio wave at a predetermined frequency (for example, a frequency of 1 GHz or more) and enables communication. The wiring board 10 may correspond to a millimeter wave antenna, a telephone antenna, a WiFi antenna, a 3G antenna, a 4G antenna, a 5G antenna, a LTE antenna, a Bluetooth (registered trademark) antenna, or a NFC antenna.

For example, the wiring board 10 may have a function such as a gesture sensing function, a wireless power supply function, an anti-fog function, a heater function, a hovering function (a function that enables an operation to be performed by a user without directly touching the display), a fingerprint authentication function, or a noise cutting (electromagnetic wave shielding) function. In the present specification, the “gesture sensing function” means a function of detecting a relative position of an object with respect to the mesh wiring layers 20 of the wiring board 10 described later (such as a distance or an angle) or the movement speed of the object. In this case, for example, the mesh wiring layers 20 of the wiring board 10 may fulfill the gesture sensing function by detecting a millimeter wave.

The wiring board 10 includes a substrate 11 that is transparent and the mesh wiring layers 20 that are disposed on the substrate 11. Power supply portions 40 are electrically connected to the mesh wiring layers 20.

The shape of the substrate 11 is a substantially rectangular shape (a rectangular shape (see FIG. 2) corner portions of which are rounded) in plan view. In an illustrated example, the longitudinal direction thereof is parallel with the X-direction, and the transverse direction thereof is parallel with the Y-direction. The substrate 11 is transparent and has a substantially plate shape, and the thickness thereof is substantially uniform as a whole. The shape of the substrate 11 can be appropriately selected depending on the shape of the first base material 96 of each display device 95 that is mounted on the frame 91.

The material of the substrate 11 is a material that is transparent and that has electrical insulation properties in a visible light region. Examples of the material of the substrate 11 preferably include polyester resin, acrylic resin, polycarbonate resin, polyimide resin, polyolefin resin, cellulose resin, and an organic insulating material such as a fluorine resin material. For example, the polyester resin may be polyethylene terephthalate. For example, the acrylic resin may be polymethyl methacrylate. For example, the polyolefin resin may be cyclic olefin polymer. For example, the cellulose resin may be triacetylcellulose. For example, the fluorine resin material may be PTFE or PFA. For example, the material of the substrate 11 may be an organic insulating material such as cyclic olefin polymer (for example, ZF-16 made by ZEON CORPORATION), or polynorbornene polymer (made by Sumitomo Bakelite Co., Ltd.). Glass or ceramics, for example, may be appropriately selected as the material of the substrate 11 depending on use. In an illustrated example, the substrate 11 has a single layer but is not limited thereto and may has a structure obtained by stacking multiple base materials or layers. The substrate 11 may be a film member or a plate member.

The substrate 11 is transparent. In the present specification, “being transparent” means that the transmittance of visible light (light at a wavelength of 400 nm or more and 700 nm or less) is 85% or more. As for the substrate 11, the transmittance of visible light (light at a wavelength of 400 nm or more and 700 nm or less) may be 85% or more and is preferably 90% or more. The upper limit of the transmittance of visible light in the substrate 11 is not particularly limited but may be, for example, 100% or less. When the transmittance of visible light in the substrate 11 ranges as described above, the visibility of the surroundings can be inhibited from being impaired when the wiring board 10 is incorporated into the HDM 90. The transmittance of visible light being 85% or more means that when absorbance is measured regarding the substrate 11 by using a known spectrophotometer (such as V-670 made by JASCO Corporation), the transmittance thereof is 85% or more at any wavelength in the entire range of a wavelength of 400 nm or more and 700 nm or less.

The tensile modulus of the substrate 11 is preferably 0.5 GPa or more and 4.5 GPa or less. When the tensile modulus of the substrate 11 is 0.5 GPa or more, the rigidity of the substrate 11 can be ensured, and the substrate 11 can be inhibited from deforming. When the tensile modulus of the substrate 11 is 4.5 GPa or less, the substrate 11 can be inhibited from being too hard. This enables the substrate 11 to be inhibited from being damaged even in the case where the substrate 11 is bent. For this reason, antenna performance can be inhibited from reducing due to the deformation of the wiring board 10. The tensile modulus of the substrate 11 can be measured in accordance with ASTM-D-882. Specifically, the elongation of a test piece is measured by using a tensile testing machine, and the tensile modulus can be acquired from the maximum elasticity (the linear expression of a tangent of the maximum slope of a stress-strain curve) right before plastic deformation.

The dielectric tangent of the substrate 11 may be 0.002 or less and is preferably 0.001 or less. The lower limit of the dielectric tangent of the substrate 11 is not particularly limited but may be more than 0. When the dielectric tangent of the substrate 11 ranges as described above, particularly, in the case where an electromagnetic wave (for example, a millimeter wave) that is transmitted and received by the mesh wiring layers 20 is a radio-frequency wave, the loss of gain (that is, a reduction in sensitivity) caused due to transmission and reception of the electromagnetic wave can be reduced.

The relative dielectric constant of the substrate 11 is preferably 2 or more and 10 or less. When the relative dielectric constant of the substrate 11 is 2 or more, the material of the substrate 11 can be selected from many choices. In addition, when the relative dielectric constant of the substrate 11 is 2 or more, a low-cost material can be selected, and manufacturing costs can be reduced. In addition, when the relative dielectric constant of the substrate 11 is 2 or more, a material suitable for manufacturing processing can be selected, a manufacturing yield can be improved, and the manufacturing costs can be reduced. When the relative dielectric constant of the substrate 11 is 10 or less, the loss of gain (sensitivity) caused due to transmission and reception of the electromagnetic wave can be reduced. That is, in the case where the relative dielectric constant of the substrate 11 increases, the influence of the thickness of the substrate 11 on the propagation of the electromagnetic wave increases. In the case where the propagation of the electromagnetic wave is negatively affected, the dielectric tangent of the substrate 11 increases, and the loss of gain caused due to transmission and reception of the electromagnetic wave can increase. When the relative dielectric constant of the substrate 11 is 10 or less, however, the influence of the thickness of the substrate 11 on the propagation of the electromagnetic wave can be reduced. For this reason, the loss of gain caused due to transmission and reception of the electromagnetic wave can be reduced. In particular, in the case where the electromagnetic wave (for example, a millimeter wave) that is transmitted and received by the mesh wiring layers 20 is a radio-frequency wave, the loss of gain caused due to transmission and reception of the electromagnetic wave can be reduced.

The dielectric tangent and relative dielectric constant of the substrate 11 can be measured in accordance with IEC 62562. Specifically, a portion of the substrate 11 at which the mesh wiring layers 20 are not formed is first cut, and a test piece is prepared. As for the dimensions of the test piece, the width is 10 mm or more and 20 mm or less, and the length is 50 mm or more and 100 mm or less. Subsequently, the dielectric tangent or the relative dielectric constant is measured in accordance with IEC 62562.

According to the present embodiment, the mesh wiring layers 20 serve as transceiver portions for the electromagnetic wave. In other words, the mesh wiring layers 20 are formed by an antenna pattern that has an antenna function. The mesh wiring layers 20 may serve as an array antenna that includes two or more antenna elements (radiating elements (end portions 20b described later)). In the case where the mesh wiring layers 20 thus serve as the array antenna, millimeter wave antenna performance for transmitting and receiving a millimeter wave that tends to travel straight can be enhanced. An array antenna means an antenna in which multiple antenna elements are regularly arranged, and the amplitude and phase of excitation of each element can be individually controlled.

As illustrated in FIG. 4, the multiple mesh wiring layers 20 are formed on the substrate 11. The number of the mesh wiring layers 20 is preferably 4 or more. In this case, the wiring board 10 includes four or more antenna elements (the end portions 20b described later). In an illustrated example, the four mesh wiring layers 20 are formed on the substrate 11 (see FIG. 2). As illustrated in FIG. 4, the mesh wiring layers 20 may not spread over the entire surface of the substrate 11 but may be disposed in only a region of the substrate 11. The mesh wiring layers 20 may have the same shape. In this case, as for each mesh wiring layer 20, an error in a length (a length in the Y-direction) Lₐ and an error in a width (a length in the X-direction) Wₐ of the end portion 20b described later are preferably within 10%. This enables the millimeter wave antenna performance can be effectively enhanced.

The mesh wiring layers 20 include base end portions (transmission portions) 20a that face the power supply portions 40 and the end portions (transceiver portions) 20b that are connected to the base end portions 20a. The base end portions 20a are connected to the power supply portions 40. In this case, the base end portions (the transmission portions) 20a may include a microstrip line or a coplanar waveguide. The shape of each base end portion 20a and the shape of each end portion 20b are substantially rectangular shapes in plan view. In this case, the widths (distances in the X-direction) of the end portions 20b are greater than the widths (distances in the X-direction) of the base end portions 20a.

The end portions 20b of the mesh wiring layers 20 correlate with predetermined frequency bands. That is, the lengths (the lengths in the Y-direction) Lₐ of the end portions 20b correlate with specific frequency bands. As the correlating frequency bands reduce, the lengths Lₐ of the end portions 20b increase. The mesh wiring layers 20 may correspond to a millimeter wave antenna, a telephone antenna, a WiFi antenna, a 3G antenna, a 4G antenna, a 5G antenna, a LTE antenna, a Bluetooth (registered trademark) antenna, or a NFC antenna. The lengths of the multiple end portions 20b may differ from each other and may correlate with different frequency bands. For example, the mesh wiring layers 20 may fulfill a hovering function, or another function such as fingerprint authentication, heating, or noise cutting (electromagnetic wave shielding).

In an illustrated example, as for the end portions 20b, the longitudinal direction thereof is parallel with the X-direction, and the transverse direction thereof is parallel with the Y-direction. As for the end portions 20b, the longitudinal direction thereof may be parallel with the Y-direction, and the transverse direction thereof is parallel with the X-direction. For example, the lengths Lₐ of the end portions 20b in the Y-direction can be selected from a range of 1 mm or more and 100 mm or less. For example, the widths Wₐ of the end portions 20b in the X-direction can be selected from a range of 1 mm or more and 100 mm or less. In particular, in the case where the mesh wiring layers 20 correspond to a millimeter wave antenna, the lengths Lₐ of the end portions 20b can be selected from a range of 1 mm or more, more preferably 1.5 mm or more. In the case where the mesh wiring layers 20 correspond to a millimeter wave antenna, the lengths Lₐ of the end portions 20b can be selected from a range of 10 mm or less, more preferably 5 mm or less.

A distance between the mesh wiring layers 20 can be appropriately set depending on the correlating frequency and is preferably 1 mm or more and 30 mm or less. That is, a distance D_{20b} (see FIG. 4) between the end portions 20 b is preferably 1 mm or more and 30 mm or less. Setting the appropriate distance enables desired antenna directivity to be obtained and enables gain to be improved.

As illustrated in FIG. 4, the patterns of the mesh wiring layers 20 are such that metal wires are disposed in the form of mesh. The patterns are repeatedly formed in the X-direction and the Y-direction. That is, the patterns of the mesh wiring layers 20 include portions (the first direction wiring lines 21 described later) that extend in the first direction (for example, the Y-direction) and portions (the second direction wiring lines 22 described later) that extend in the second direction (for example, the X-direction).

As illustrated in FIG. 5, the mesh wiring layers 20 include the wiring lines. Specifically, the mesh wiring layers 20 include the multiple first direction wiring lines (the wiring lines) 21 and the multiple second direction wiring lines (the wiring lines) 22 that couple the multiple first direction wiring lines 21 with each other. The multiple first direction wiring lines 21 and the multiple second direction wiring lines 22 are formed into one piece as a whole in the form of mesh. The first direction wiring lines 21 extend in the longitudinal direction (the Y-direction) of the mesh wiring layers 20. The second direction wiring lines extend in the width direction (the X-direction) of the mesh wiring layers 20. The first direction wiring lines 21 and the second direction wiring lines 22 may extend in directions parallel with neither the X-direction nor the Y-direction.

Planar shapes of the first direction wiring lines 21 and the second direction wiring lines 22 have multiple curves that are connected to each other. In this case, the curves are arcs or elliptical arcs. In an illustrated example, the planar shapes of the first direction wiring lines 21 and the second direction wiring lines 22 have multiple arcs that are connected to each other. A diffraction image that appears due to a linear structure extends in a direction perpendicular to the longitudinal direction of the structure and becomes a beam of light (streak of light that is observed so as to leave a trail). In the case where the planar shapes of the first direction wiring lines 21 and the second direction wiring lines 22 have the multiple arcs that are connected to each other, the beams of light that appear extend in various directions. In the case where the beams of light that appear extend in various directions, beams of light are superimposed on each other, and consequently, it is difficult to recognize each of the beams of light. This enables an influence of the beam of light on the visibility to be reduced. In the case where the curves are elliptical arcs, the length of the major axis of an ellipse that is formed by the elliptical arcs may be more than 1 times and 1.1 times or less the length of the minor axis.

As for the mesh wiring layers 20, opening portions 23 are formed by being surrounded by the first direction wiring lines 21 and the second direction wiring lines 22. Specifically, as for the mesh wiring layers 20, the multiple opening portions 23 are formed by being surrounded by the first direction wiring lines 21 adjacent to each other and the second direction wiring lines 22 adjacent to each other. The substrate 11 that is transparent is exposed from the opening portions 23. This enables the transparency of the wiring board 10 as a whole to be enhanced.

As for the first direction wiring lines 21 and the second direction wiring lines 22 that surround the opening portions 23, a shape obtained by connecting end portions of chords of the multiple arcs (curves) is a polygonal shape. In this case, a side of the polygonal shape may be formed by 2N (N is a natural number of 1 or more) chords. According to the present embodiment, the side of the polygonal shape is formed by 2 (N=1) chords. According to the present embodiment, as for the first direction wiring lines 21 and the second direction wiring lines 22 that surround the opening portions 23, the shape obtained by connecting the end portions of the chords of the multiple arcs (curves) is a square shape. That is, straight lines L1 that connect the end portions of the chords of the first direction wiring lines 21 to each other and straight lines L2 that connect the end portions of the chords of the second direction wiring lines 22 to each other are arranged at a regular interval. The straight lines L1 that connect the end portions of the chords of the first direction wiring lines 21 are arranged at a regular interval, and the range of the pitch P₁ thereof can be, for example, 0.01 mm or more and 1 mm or less. The straight lines L2 that connect the end portions of the chords of the second direction wiring lines 22 are arranged at a regular interval, and the range of the pitch P₂ thereof can be, for example, 0.01 mm or more and 1 mm or less. Consequently, the sizes of the opening portions 23 in the mesh wiring layers 20 do not vary, and the mesh wiring layers 20 can be unlikely to be visually recognized with the naked eye. The straight lines L1 and the straight lines L2 are perpendicular to each other, but are not limited thereto, and may be intersect with each other at an acute angle or an obtuse angle. The shapes of the opening portions 23 are preferably the same shape having the same size over the entire surface but may be changed depending on a location and may not be uniform over the entire surface. The side of the polygonal shape may be formed by 4 or more (N≥2) chords or may be formed by an odd number of chords although this is not illustrated.

The first direction wiring lines 21 and the second direction wiring lines 22 may have a shape obtained by connecting multiple arcs that are cut at a central angle of 160° or more and 200° or less to each other. In this case, the diameter of a circle from which the arcs are cut may be 0.4 times or more and 0.6 times or less the length of a side of a square shape S1 that is formed by the straight lines L1 and the straight lines L2. In the present specification, the square shape S1 that is formed by the straight lines L1 and the straight lines L2 means a square shape (see hatching portions in FIG. 5) that has the minimum area among regions (square shapes) that are surrounded by the straight lines L1 and the straight lines L2.

An M-th dividing point is an M-th (M is a natural number of 1 or more and (2N−1) or less) dividing point on a side of the square shape (the polygonal shape) S1 from an end portion E₁ of end portions E₁ and E₂ of the side among dividing points at which the side is equally divided into 2N pieces. An M-th connection point is an M-th connection point on the side from the end portion E₁ of the side among connection points of the chords. In this case, the distance from the M-th dividing point to the M-th connection point may be 0.1/N times or less the length of the side.

According to the present embodiment, the side of the polygonal shape is formed by the two chords, and N=1 is satisfied as described above. For this reason, the dividing point on the side at which the side is divided into 2N pieces includes only a first dividing point DiP₁ (M=1) that is a first (M=1) dividing point from the end portion E₁ of the side. According to the present embodiment, the first dividing point DiP₁ is a middle point of the side. The connection point of the chords on the side includes only a first connection point CP₁ that is a first (M=1) connection point from the end portion E₁ of the side.

In the case of N=1 and M=1 as described above, the minimum distance Dₚ₁ from the first dividing point DiP₁ to the first connection point CP₁ may be 0.1 times or less (N=1) the length of the side as illustrated by an imaginary line (a two-dot chain line) in FIG. 5. In the case where the first direction wiring lines 21 and the second direction wiring lines 22 have a shape obtained by connecting arcs that satisfy the above relationship to each other, substantially perfect circles can be formed by connecting the first direction wiring lines 21 and the second direction wiring lines 22 that surround the opening portions 23. The imaginary line in FIG. 5 is a curve obtained by connecting two arcs to each other when the first connection point CP₁ is not the middle point (the first dividing point DiP₁) of the side.

According to the present embodiment, as illustrated in FIG. 5, the first direction wiring lines 21 have a shape obtained by connecting multiple arcs that are cut at a central angle θ1 of 180°. In this case, the diameter of a circle C1 from which the arcs are cut is 0.5 times the length of the side of the square shape S1 that is formed by the straight lines L1 and the straight lines L2. The first connection point CP₁ is located on the first dividing point DiP₁ (the middle point of the side) on the side of the square shape S1 that is formed by the straight lines L1 and the straight lines L2. The second direction wiring lines 22 have a shape obtained by connecting multiple arcs that are cut at a central angle θ2 of 180°. In this case, the diameter of a circle C2 from which the arcs are cut is 0.5 times the length of the side of the square shape S1 that is formed by the straight lines L1 and the straight lines L2. The first connection point CP₁ is located on the first dividing point DiP₁ (the middle point of the side) on the side of the square shape S1 that is formed by the straight lines L1 and the straight lines L2. In this case, for example, a perfect circle can be formed by connecting the second direction wiring lines 22, 22a that form the upper straight line L1 among the first direction wiring lines 21 and the second direction wiring lines 22 that surround the opening portions 23 (see stippling portions in FIG. 5). The perfect circle described herein means a circle that is formed such that arcs are not superimposed on each other when curves are connected to each other. In this case, multiple perfect circles can be formed by connecting the first direction wiring lines 21 and the second direction wiring lines 22 that surround the opening portions 23 (see the stippling portions in FIG. 5). In the present specification, the opening portions 23 mean regions (see the stippling portions in FIG. 5) that have the minimum area among regions that are surrounded by the first direction wiring lines 21 and the second direction wiring lines 22.

The diffraction image that appears due to the linear structure extends in the direction perpendicular to the longitudinal direction of the structure and becomes the beam of light (the streak of light that is observed so as to leave the trail) as described above. In the case where the beams of light that appear extend in all directions (360°), it is difficult to recognize each of the beams of light. That is, many beams of light are superimposed on each other into a circular shape, and consequently, the influence of the beam of light on the visibility can be reduced. Accordingly, normal lines perpendicular to the longitudinal direction of the first direction wiring lines 21 and the second direction wiring lines 22 that surround one of the opening portions 23 extend in all directions such that the beams of light extend in all directions, and consequently, many beams of light are superimposed on each other and are visually recognized as a circular shape.

According to the present embodiment, however, the first direction wiring lines 21 and the second direction wiring lines 22 can have a shape obtained by connecting multiple arcs that are cut at a central angle of 160° or more and 200° or less. The minimum distance Dₚ₁ from the first dividing point DiP₁ to the first connection point CP₁ can be 0.1 times or less the length of the side. This enables the normal lines perpendicular to the longitudinal direction of the first direction wiring lines 21 and the second direction wiring lines 22 that surround the opening portions 23 (see the stippling portions in FIG. 5) to be distributed in substantially all directions. For this reason, the visibility can be more effectively inhibited from reducing due to the beam of light. In particular, in the case where the first direction wiring lines 21 and the second direction wiring lines 22 have a shape obtained by connecting multiple arcs that are cut at a central angle θ1 of 180° and a central angle θ2 of 180° from the circles C1 and C2 that have a diameter of 0.5 times the side of the square shape S1 that is formed by the straight lines L1 and the straight lines L2, and the first connection point CP₁ is located on the first dividing point DiP₁ (the middle point of the side), the normal lines described above are distributed in all directions. For this reason, the visibility can be further effectively inhibited from reducing due to the beam of light.

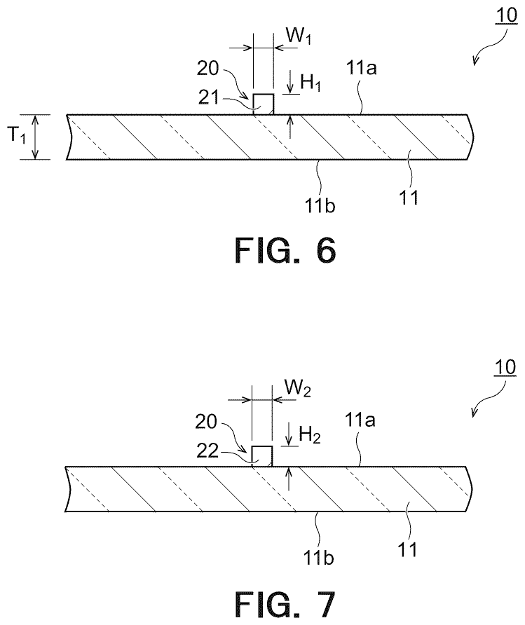

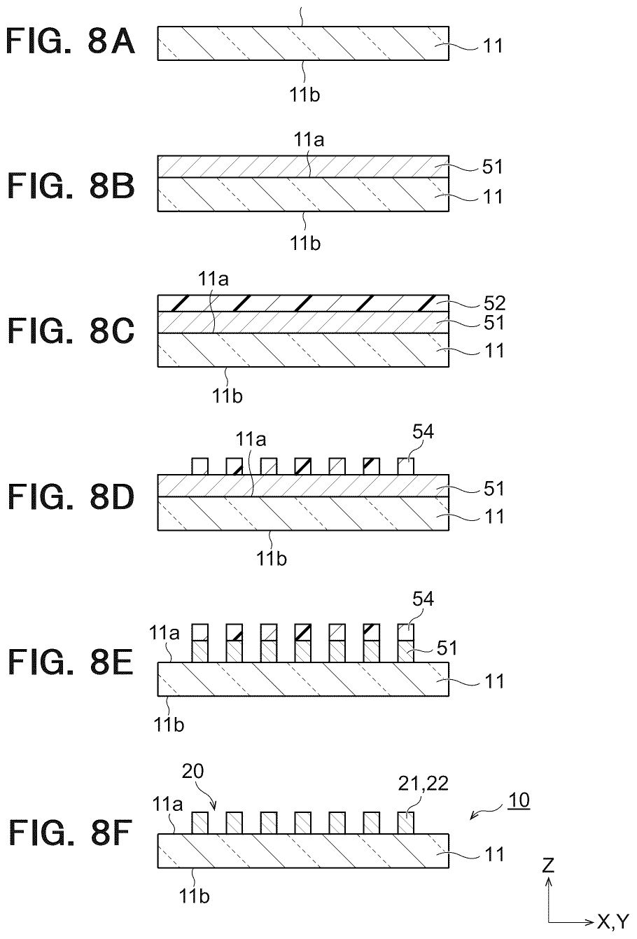

As illustrated in FIG. 6, a section of each first direction wiring line 21 perpendicular to the longitudinal direction thereof has a substantially rectangular shape or a substantially square shape. In this case, the shape of the section of each first direction wiring line 21 is substantially uniform in the longitudinal direction of the first direction wiring line 21. As illustrated in FIG. 7, a section of each second direction wiring line 22 perpendicular to the longitudinal direction thereof has a substantially rectangular shape or a substantially square shape and is substantially the same as that of the section of each first direction wiring line 21 described above. In this case, the shape of the section of each second direction wiring line 22 is substantially uniform in the longitudinal direction of the second direction wiring line 22. The shape of the section of each first direction wiring line 21 and the shape of the section of each second direction wiring line 22 may not necessarily be a substantially rectangular shape or a substantially square shape. For example, the shape of the section of each first direction wiring line 21 and the shape of the section of each second direction wiring line 22 may be a substantially trapezoid shape a front surface (in the positive Z-direction) of which is narrower than a back surface (in the negative Z-direction) or a shape in which both side surfaces in the width direction are curved.

According to the present embodiment, the linewidths W₁ (see FIG. 6) of the first direction wiring lines 21 and the linewidths W₂ (see FIG. 7) of the second direction wiring lines 22 are not particularly limited but may be appropriately selected depending on use. The linewidths W₁ of the first direction wiring lines 21 correspond to widths in a section perpendicular to the longitudinal direction thereof, and the linewidths W₂ of the second direction wiring lines 22 correspond to widths in a section perpendicular to the longitudinal direction thereof. For example, the linewidths W₁ of the first direction wiring lines 21 can be selected from a range of 0.1 μm or more and 5.0 μm or less and may be 0.2 μm or more and 2.0 μm or less. The linewidths W₂ of the second direction wiring lines 22 can be selected from a range of 0.1 μm or more and 5.0 μm or less and may be 0.2 μm or more and 2.0 μm or less.

The heights H₁ (see FIG. 6) of the first direction wiring lines 21 and the heights H₂ (see FIG. 7) of the second direction wiring lines 22 are not particularly limited but can be appropriately selected depending on use. The heights H₁ of the first direction wiring lines 21 and the heights H₂ of the second direction wiring lines 22 described herein correspond to lengths in the Z-direction. For example, the heights H₁ of the first direction wiring lines 21 and the heights H₂ of the second direction wiring lines 22 can be selected from a range of 0.1 μm or more and may be 0.2 μm or more. For example, the heights H₁ of the first direction wiring lines 21 and the heights H₂ of the second direction wiring lines 22 can be selected from a range of 5.0 μm or less and may be 2.0 μm or less.

The materials of the first direction wiring lines 21 and the second direction wiring lines 22 are conductive metal materials. According to the present embodiment, the materials of the first direction wiring lines 21 and the second direction wiring lines 22 are copper but are not limited thereto. Examples of the materials of the first direction wiring lines 21 and the second direction wiring lines 22 can include metal materials such as gold, silver, copper, platinum, tin, aluminum, iron, and nickel and alloys that contain these metal. The first direction wiring lines 21 and the second direction wiring lines 22 may be plating layers that are formed by using an electroplating method.

For example, the aperture ratios At of the mesh wiring layers 20 as a whole may be in a range of 87% or more and less than 100%. When the aperture ratios At of the mesh wiring layers 20 as a whole are in this range, the transparency and conductivity of the wiring board 10 can be ensured. The aperture ratios At of the mesh wiring layers 20 as a whole are preferably 94% or more and less than 100%. This ensures the conductivity of the wiring board 10 and enables the transparency of the wiring board 10 to be enhanced. An aperture ratio is the percentage (%) of the area of an opening region that occupies a predetermined region (for example, the entire region of each mesh wiring layer 20) per unit area. The opening region is a region in which metal portions such as the first direction wiring lines 21 and the second direction wiring lines 22 are not present, where the substrate 11 is exposed.

A protective layer may be formed on a first surface 11a of the substrate 11 so as to cover the mesh wiring layers 20 although this is not illustrated. The protective layer protects the mesh wiring layers 20 and is formed so as to cover at least the mesh wiring layers 20 on the substrate 11. Examples of the material of the protective layer can include acrylic resin such as polymethyl (meth) acrylate and polyethyl (meth) acrylate, modified resin thereof, copolymer thereof, polyvinyl resin such as polyester, polyvinyl alcohol, polyvinyl acetate, polyvinyl acetal, and polyvinyl butyral, copolymer thereof, and colorless transparent insulating resin such as polyurethane, epoxy resin, polyamide, and chlorinated polyolefin.

In the case where a flex resistance test is performed on the wiring board 10, an increase in the resistance value of each mesh wiring layer 20 may be 10% or less or may be 5% or less. The flex resistance test means a test in which the wiring board 10 is bent 180° around a cylinder having a diameter of 1 mm and is subsequently stretched, and this is repeated 100 times by using a cylindrical mandrel flex tester.

Specifically, the test is performed as described below. An electric resistance value between both ends of each mesh wiring layer 20 in the longitudinal direction is measured. The resistance value at this time is R₀ (Ω). Subsequently, the wiring board 10 is wound around the cylinder of the cylindrical mandrel flex tester such that both ends of the wiring board 10 in the longitudinal direction face in opposite directions at 180°. Subsequently, the wiring board 10 is removed from the cylinder and stretched into a flat shape. This operation is repeated 100 times. Subsequently, the electric resistance value between both ends of each mesh wiring layer 20 in the longitudinal direction is measured again. The resistance value at this time is R₁ (Ω). At this time, a value obtained from ((R₁−R₀)/R₀)×100 (%) is the increase in the resistance value. When the increase in the resistance value is 10% or less, the durability of the wiring board 10 can be improved in the case where the wiring board 10 is used so as to curve or bend.

Referring to FIG. 4 again, the power supply portions 40 are electrically connected to the mesh wiring layers 20. The power supply portions 40 include conductive thin plate members that have a substantially rectangular shape.

The power supply portions 40 are disposed at end portions of the substrate 11 in the longitudinal direction (end portions in the negative Y-direction). Examples of the materials of the power supply portions 40 can include metal materials such as gold, silver, copper, platinum, tin, aluminum, iron, and nickel and alloys that contain these metal.

The power supply portions 40 are electrically connected to the wireless communication circuits 94a that are provided on the frame 91 of the HMD 90 when the wiring board 10 is incorporated into the HDM 90 (see FIG. 2). The power supply portions 40 are preferably provided so as to overlap the rim 92 of the frame 91 in front view of the HMD 90. This enables the mesh wiring layers 20 and the wireless communication circuits 94a to be easily connected to each other and enables the visibility of the surroundings to be inhibited from being impaired. The power supply portions 40 are provided on the first surface 11a of the substrate 11 but are not limited thereto, and some or all of the power supply portions 40 may be located outside the periphery of the substrate 11.

### Method of Manufacturing Wiring Board

A method of manufacturing the wiring board 10 according to the present embodiment will now be described with reference to FIG. 8A to FIG. 8F.

As illustrated in FIG. 8A, the substrate 11 that has the first surface 11a and a second surface 11b that is located opposite the first surface 11a is first prepared. The substrate 11 is transparent.

Subsequently, the mesh wiring layers 20 and the power supply portions 40 that are electrically connected to the mesh wiring layers 20 are formed on the first surface 11a of the substrate 11.

At this time, as illustrated in FIG. 8B, metal foil 51 is stacked over the substantially entire region of the first surface 11a of the substrate 11. According to the present embodiment, the thickness of the metal foil 51 may be 0.1 μm or more and 5.0 μm or less. According to the present embodiment, the metal foil 51 may contain copper.

Subsequently, as illustrated in FIG. 8C, photocurable insulating resist 52 is applied to the substantially entire region of the front surface of the metal foil 51. Examples of the photocurable insulating resist 52 include organic resin such as acrylic resin and epoxy resin.

Subsequently, as illustrated in FIG. 8D, an insulating layer 54 is formed by using a photolithography method. In this case, the photocurable insulating resist 52 is patterned by using the photolithography method, and the insulating layer 54 (a resist pattern) is formed. At this time, the insulating layer 54 is formed such that the metal foil 51 that corresponds to the first direction wiring lines 21 and the second direction wiring lines 22 is exposed.

Subsequently, as illustrated in FIG. 8E, a portion of the metal foil 51 on the first surface 11a of the substrate 11 that is not covered by the insulating layer 54 is removed. At this time, wet processing is performed by using strong acid such as ferric chloride, cupric chloride, sulfuric acid or hydrochloric acid, persulfate, hydrogen peroxide, an aqueous solution thereof, or a combination thereof, and consequently, the metal foil 51 is etched such that the first surface 11a of the substrate 11 is exposed.

Subsequently, as illustrated in FIG. 8F, the insulating layer 54 is removed. In this case, wet processing is performed by using a permanganate solution, N-methyl-2-pyrrolidone, an acid, or alkali solution, or dry processing is performed by using oxygen plasma, and consequently, the insulating layer 54 on the metal foil 51 is removed.

In this way, the wiring board 10 that includes the substrate 11 and the mesh wiring layers 20 that are provided on the first surface 11a of the substrate 11 is obtained. In this case, the mesh wiring layers 20 include the first direction wiring lines 21 and the second direction wiring lines 22. At this time, the power supply portions 40 may be formed by using a portion of the metal foil. Alternatively, the power supply portions 40 that have a plate shape may be prepared, and the power supply portions 40 may be electrically connected to the mesh wiring layers 20.

The wiring board 10 is mounted on the first base material 96 that is fitted into the rim 92 of the frame 91, and consequently, the HMD 90 illustrated in FIG. 1 is obtained. The wiring board 10 may be mounted on the first base material 96 before the first base material 96 is fitted into the rim 92 of the frame 91.

### Actions According to Present Embodiment

Actions according to the present embodiment that is thus configured will now be described.

As illustrated in FIG. 2, the wiring board 10 is incorporated into the HMD 90 as a component of each display device 95. The mesh wiring layers 20 of the wiring board 10 are electrically connected to the wireless communication circuits 94a of the HMD 90 with the power supply portions 40 interposed therebetween. In this way, the radio wave at the predetermined frequency can be transmitted and received via the mesh wiring layers 20, and the use of the HMD 90 enables communication.

According to the present embodiment, the planar shapes of the first direction wiring lines 21 and the second direction wiring lines 22 have the multiple arcs that are connected to each other. Consequently, the beams of light that appear extend in various directions. For this reason, the beams of light are superimposed on each other, and consequently, it is difficult to recognize each of the beams of light. As a result, the visibility can be inhibited from reducing due to the beam of light. In this case, variations in the pitches of the first direction wiring lines 21 and the second direction wiring lines 22 and the pitch of the second direction wiring lines 22 do not increase, and the visibility can be inhibited from reducing due to the beam of light. For this reason, flicker due to the reflection of visible light because of the mesh wiring layers 20 can be reduced. The planar shapes of the first direction wiring lines 21 and the second direction wiring lines 22 have the multiple arcs that are connected to each other, and consequently, the reflection of the electromagnetic wave at the first direction wiring lines 21 and the second direction wiring lines 22 can be reduced. For this reason, the transmission efficiency of the wiring board 10 can be increased.

As for the HMD 90 according to the present embodiment, the wiring board 10 includes the substrate 11 that is transparent and the mesh wiring layers 20 that are disposed on the substrate 11. The aperture ratios of the mesh wiring layers 20 are 94% or more. For this reason, the transparency of the wiring board 10 can be ensured. This enables the surroundings to be visually recognized through the opening portions 23 of the mesh wiring layers 20 when the wiring board 10 is incorporated into the HMD 90, and the visibility of the surroundings is not impeded.

Modifications to the wiring board will now be described.

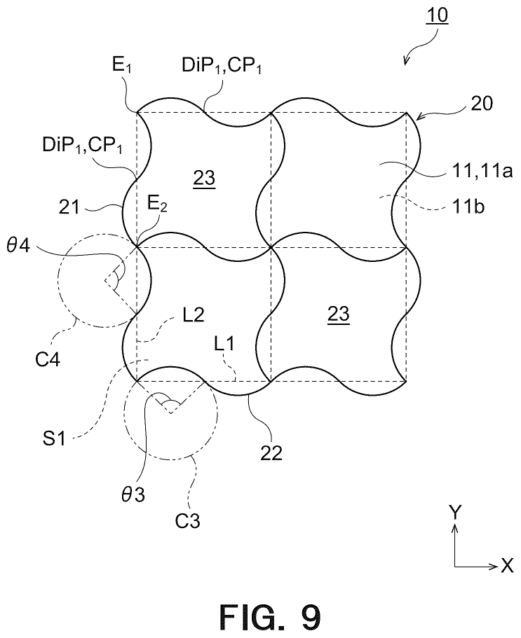

FIG. 9 illustrates a first modification to the wiring board 10. The modification illustrated in FIG. 9 differs in that the first direction wiring lines 21 and the second direction wiring lines 22 have a shape obtained by connecting multiple arcs that are cut at a central angle of 80° or more and 100° or less, and the other components are substantially the same as those according to the embodiment illustrated in FIG. 1 to FIG. 8F described above. In FIG. 9, components like to those according to the embodiment illustrated in FIG. 1 to FIG. 8F are designated by using like reference signs, and a detailed description is omitted.

As for the wiring board 10 illustrated in FIG. 9, the first direction wiring lines 21 and the second direction wiring lines 22 have a shape obtained by connecting multiple arcs that are cut at a central angle of 80° or more and 100° or less. In this case, the diameter of a circle from which the arcs are cut may be (1/√2)×0.8 times or more and (1/√2)×1.2 times or less the length of the side of the square shape S1 that is formed by the straight lines L1 and the straight lines L2. Also according to the present modification, the minimum distance Dₚ₁ (see FIG. 5) from the first dividing point DiP₁ to the first connection point CP₁ on the side of the square shape S1 that is formed by the straight lines L1 and the straight lines L2 may be 0.1 times or less the length of the side. Even in the case where the first direction wiring lines 21 and the second direction wiring lines 22 have a shape obtained by connecting arcs that satisfy the relationship described above to each other, substantially perfect circles can be formed by connecting the first direction wiring lines 21 and the second direction wiring lines 22 that surround the opening portions 23.

According to the present modification, as illustrated in FIG. 9, the first direction wiring lines 21 have a shape obtained by connecting multiple arcs that are cut at a central angle θ3 of 90°. In this case, the diameter of a circle C3 from which the arcs are cut is 1/√2 times the length of the side of the square shape S1 that is formed by the straight lines L1 and the straight lines L2. The first connection point CP₁ is located on the first dividing point DiP₁ (the middle point of the side) on the side of the square shape S1 that is formed by the straight lines L1 and the straight lines L2. The second direction wiring lines 22 have a shape obtained by connecting multiple arcs that are cut at a central angle θ4 of 90°. In this case, the diameter of a circle C4 from which the arcs are cut is 1/√2 times the length of the side of the square shape S1 that is formed by the straight lines L1 and the straight lines L2. The first connection point CP₁ is located on the first dividing point DiP₁ (the middle point of the side) on the side of the square shape S1 that is formed by the straight lines L1 and the straight lines L2. Also in this case, multiple perfect circles can be formed by connecting the first direction wiring lines 21 and the second direction wiring lines 22 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light.

According to the present modification, the first direction wiring lines 21 have a shape obtained by connecting multiple arcs that are cut at a central angle θ3 of 80° or more and 100° or less to each other, and the second direction wiring lines 22 have a shape obtained by connecting multiple arcs that are cut at a central angle θ4 of 80° or more and 100° or less to each other. In this case, as for the first direction wiring lines 21 and the second direction wiring lines 22 that surround the opening portions 23, a difference between the line length of the shape (polygonal shape) obtained by connecting the end portions of the chords of the multiple curves and the total line length of the first direction wiring lines 21 and the second direction wiring lines 22 can be reduced. In other words, when the central angle θ3 and the central angle θ4 are 80° or more and 100° or less, the increase rate of the total line length of the first direction wiring lines 21 and the second direction wiring lines 22 with respect to the polygonal shape described above can be lower than that in the case where the central angle θ3 and the central angle θ4 are, for example, 180°. This enables the resistance value of each mesh wiring layer 20 to be inhibited from increasing.

Since the increase rate of the line length described above can be reduced, the aperture ratios of the mesh wiring layers 20 can be inhibited from reducing. Since the increase rate of the line length described above can be reduced, the line length of the first direction wiring lines 21 and the line length of the second direction wiring lines 22 can be inhibited from being too long. For this reason, the risk of disconnection of the first direction wiring lines 21 and the second direction wiring lines 22 can be reduced. Since the line length of, for example, the first direction wiring lines 21 and the line length of the second direction wiring lines 22 can be inhibited from being too long, patterning precision when the first direction wiring lines 21 and the second direction wiring lines 22 are manufactured and the stability of the dimensions of the first direction wiring lines 21 and the second direction wiring lines 22 can be improved. For this reason, the productivity of the wiring board 10 can be improved.

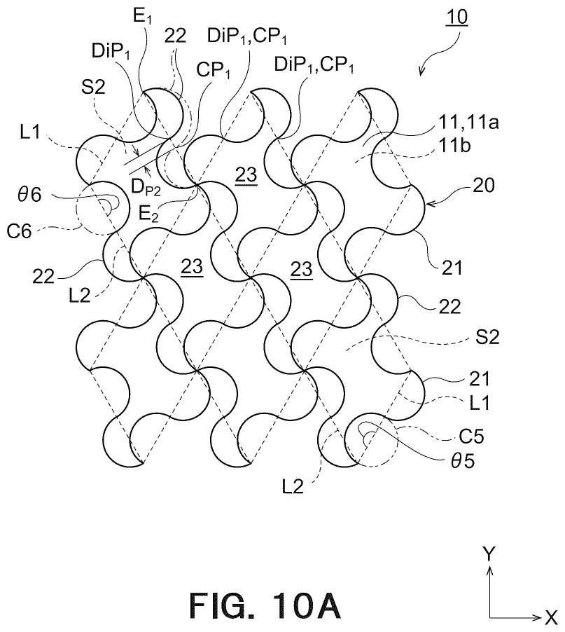

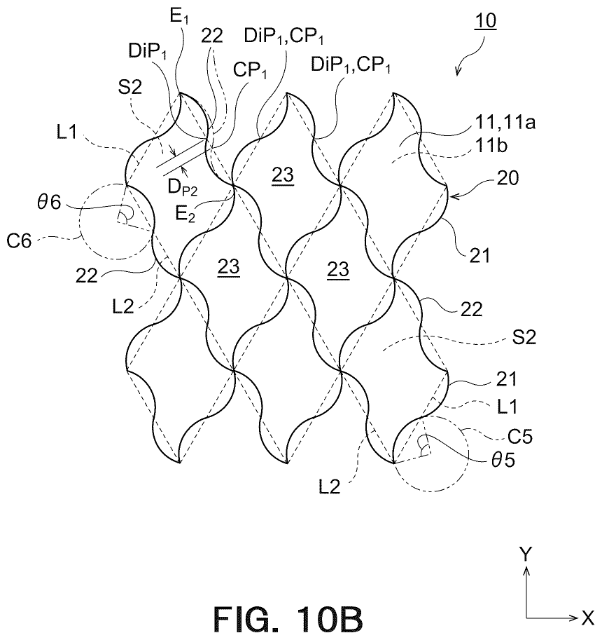

FIG. 10A illustrates a second modification to the wiring board 10. The modification illustrated in FIG. 10A differs in that as for the first direction wiring lines 21 and the second direction wiring lines 22 that surround the opening portions 23, the shape obtained by connecting the end portions of the chords of the multiple curves is a rhomboidal shape. The other components are substantially the same as those according to the embodiment illustrated in FIG. 1 to FIG. 9 described above. In FIG. 10A, components like to those according to the embodiment illustrated in FIG. 1 to FIG. 9 are designated by using like reference signs, and a detailed description is omitted.

As for the wiring board 10 illustrated in FIG. 10A, and the first direction wiring lines 21 and the second direction wiring lines 22 that surround the opening portions 23, the shape obtained by connecting the end portions of the chords of the multiple curves is a rhomboidal shape. In other words, the polygonal shape described above is a rhomboidal shape. In this case, the first direction wiring lines 21 and the second direction wiring lines 22 extend in directions parallel with neither the X-direction nor the Y-direction. This enables resistance in the Y-direction in which an electric current flows to be reduced. For this reason, antenna characteristics can be improved.

The first direction wiring lines 21 and the second direction wiring lines 22 have a shape obtained by connecting multiple arcs that are cut at a central angle of 160° or more and 200° or less. In this case, the diameter of a circle from which the arcs are cut may be 0.4 times or more and 0.6 times or less the length of a side of a rhomboidal shape S2 that is formed by the straight lines L1 and the straight lines L2. As illustrated by an imaginary line (a two-dot chain line) in FIG. 10A, a minimum distance Dₚ₂ from the first dividing point DiP₁ to the first connection point CP₁ on the side of the rhomboidal shape S2 that is formed by the straight lines L1 and straight lines L2 may be 0.1 times or less the length of the side. Also in the case where the first direction wiring lines 21 and the second direction wiring lines 22 have a shape obtained by connecting arcs that satisfy the relationship described above to each other, substantially perfect circles can be formed by connecting the first direction wiring lines 21 and the second direction wiring lines 22 that surround the opening portions 23. The imaginary line in FIG. 10A is a curve obtained by connecting two arcs to each other when the first connection point CP₁ is not the middle point (the first dividing point DiP₁) of the side.

According to the present modification, as illustrated in FIG. 10A, the first direction wiring lines 21 have a shape obtained by connecting multiple arcs that are cut at a central angle θ5 of 180° to each other. In this case, the diameter of a circle C5 from which the arcs are cut is 0.5 times the length of the side of the rhomboidal shape S2 that is formed by the straight lines L1 and the straight lines L2. The first connection point CP₁ is located on the first dividing point DiP₁ (the middle point of the side) on the side of the rhomboidal shape S2 that is formed by the straight lines L1 and the straight lines L2. The second direction wiring lines 22 have a shape obtained by connecting multiple arcs that are cut at a central angle θ6 of 180°. In this case, the diameter of a circle C6 from which the arcs are cut is 0.5 times the length of the side of the rhomboidal shape S2 that is formed by the straight lines L1 and the straight lines L2. The first connection point CP₁ is located on the first dividing point DiP₁ (the middle point of the side) on the side of the rhomboidal shape S2 that is formed by the straight lines L1 and the straight lines L2. Also in this case, multiple perfect circles can be formed by connecting the first direction wiring lines 21 and the second direction wiring lines 22 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light.

As for the wiring board 10 illustrated in FIG. 10A, an example in which the first direction wiring lines 21 and the second direction wiring lines 22 have a shape obtained by connecting multiple arcs that are cut at a central angle of 160° or more and 200° or less to each other is described, but this is not a limitation. For example, the first direction wiring lines 21 and the second direction wiring lines 22 may have a shape obtained by connecting multiple arcs that are cut at a central angle of 80° or more and 100° or less to each other. Also in this case, the diameter of a circle from which the arcs are cut may be 0.4 times or more and 0.6 times or less the length of the side of the rhomboidal shape S2 that is formed by the straight lines L1 and the straight lines L2. As illustrated by an imaginary line (a two-dot chain line) in FIG. 10B, the minimum distance Dₚ₂ from the first dividing point DiP₁ to the first connection point CP₁ on the side of the rhomboidal shape S2 that is formed by the straight lines L1 and the straight lines L2 may be 0.1 times or less the length of the side. The imaginary line in FIG. 10B is a curve obtained by connecting two arcs to each other when the first connection point CP₁ is not the middle point (the first dividing point DiP₁) of the side.

According to the present modification, as illustrated in FIG. 10B, the first direction wiring lines 21 have a shape obtained by connecting multiple arcs that are cut at a central angle θ5 of 90° to each other. Also in this case, the diameter of the circle C5 from which the arcs are cut is 0.5 times the length of the side of the rhomboidal shape S2 that is formed by the straight lines L1 and the straight lines L2. The first connection point CP₁ is located on the first dividing point DiP₁ (the middle point of the side) on the side of the rhomboidal shape S2 that is formed by the straight lines L1 and the straight lines L2. The second direction wiring lines 22 have a shape obtained by connecting multiple arcs that are cut at a central angle θ6 of 90° to each other. Also in this case, the diameter of the circle C6 from which the arcs are cut is 0.5 times the length of the side of the rhomboidal shape S2 that is formed by the straight lines L1 and the straight lines L2. The first connection point CP₁ is located on the first dividing point DiP₁ (the middle point of the side) on the side of the rhomboidal shape S2 that is formed by the straight lines L1 and the straight lines L2.

Also in an example illustrated in FIG. 10B, multiple perfect circles can be formed by connecting the first direction wiring lines 21 and the second direction wiring lines 22 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light. Also in the example illustrated in FIG. 10B, the increase rate of the total line length of the first direction wiring lines 21 and the second direction wiring lines 22 with respect to the polygonal shape described above can be reduced, and the resistance value of each mesh wiring layer 20 can be inhibited from increasing. Since the increase rate of the line length described above can be reduced, the aperture ratios of the mesh wiring layers 20 can be inhibited from reducing. Also in the example illustrated in FIG. 10B, since the line length of the first direction wiring lines 21 and the line length of the second direction wiring lines 22 can be inhibited from being too long, the risk of disconnection of the first direction wiring lines 21 and the second direction wiring lines 22 can be reduced. In addition, the patterning precision when the first direction wiring lines 21 and the second direction wiring lines 22 are manufactured and the stability of the dimensions of the first direction wiring lines 21 and the second direction wiring lines 22 can be improved. For this reason, the productivity of the wiring board 10 can be improved.

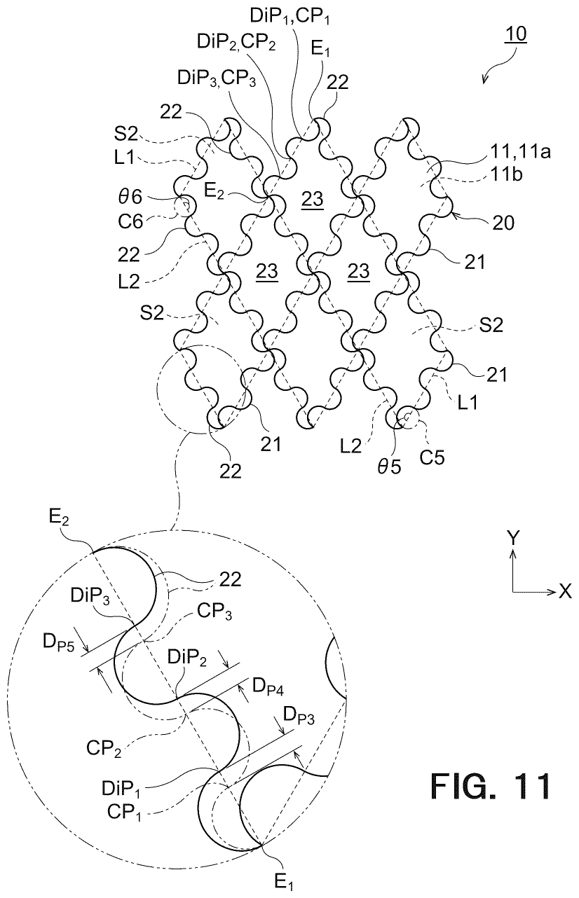

FIG. 11 illustrates a third modification to the wiring board 10. The modification illustrated in FIG. 11 differs in that the side of the rhomboidal shape S2 is formed by four (N=2) chords, and the other components are substantially the same as those according to the embodiment illustrated in FIG. 1 to FIG. 10B described above. In FIG. 11, components like to those according to the embodiment illustrated in FIG. 1 to FIG. 10B are designated by using like reference signs, and a detailed description is omitted.

As for the wiring board 10 illustrated in FIG. 11, the side of the rhomboidal shape S2 is formed by the four (N=2) chords. For this reason, dividing points on the side at which the side is divided into four pieces (N=2) are three dividing points of the first dividing point DiP₁, a second dividing point DiP₂, and a third dividing point DiP₃. Among these, the second dividing point DiP₂ is the middle point of the side. The connection points of the chords on the side are three connection points of the first connection point CP₁, a second connection point CP₂ and a third connection point CP₃.

According to the present modification, as illustrated by an imaginary line (a two-dot chain line) in FIG. 11, a minimum distance Dₚ₃ from the first dividing point DiP₁ to the first connection point CP₁ on the side of the rhomboidal shape S2 may be 0.05 times (N=2) or less the length of the side. A minimum distance Dₚ₄ from the second dividing point DiP₂ to the second connection point CP₂ on the side of the rhomboidal shape S2 may be 0.05 times (N=2) or less the length of the side. A minimum distance Dₚ₅ from the third dividing point DiP₃ to the third connection point CP₃ on the side of the rhomboidal shape S2 may be 0.05 times (N=2) or less the length of the side. Even in the case where the first direction wiring lines 21 and the second direction wiring lines 22 have a shape obtained by connecting arcs that satisfy the relationship described above to each other, substantially perfect circles can be formed by connecting the first direction wiring lines 21 and the second direction wiring lines 22 that surround the opening portions 23. The imaginary line in FIG. 11 is a curve obtained by connecting four arcs to each other when the first connection point CP₁ is not the first dividing point DiP₁, the second connection point CP₂ is not the second dividing point DiP₂, and the third connection point CP₃ is not the third dividing point DiP₃.

As illustrated in FIG. 11, the diameters of the circle C5 and the circle C6 from which the arcs are cut are 0.25 times the length of the side of the rhomboidal shape S2. The first connection point CP₁ is located on the first dividing point DiP₁, the second connection point CP₂ is located on the second dividing point DiP₂ (the middle point of the side), and the third connection point CP₃ is located on the third dividing point DiP₃ on the side of the rhomboidal shape S2 that is formed by the straight lines L1 and the straight lines L2.

According to the present modification, as illustrated in FIG. 11, the minimum distance Dₚ₃ from the first dividing point DiP₁ to the first connection point CP₁ on the side of the rhomboidal shape S2 is 0.05 times (N=2) or less the length of the side. The minimum distance Dₚ₄ from the second dividing point DiP₂ to the second connection point CP₂ on the side of the rhomboidal shape S2 is 0.05 times (N=2) or less the length of the side. The minimum distance Dₚ₅ from the third dividing point DiP₃ to the third connection point CP₃ on the side of the rhomboidal shape S2 is 0.05 times (N=2) or less the length of the side. Also in this case, multiple perfect circles can be formed by connecting the first direction wiring lines 21 and the second direction wiring lines 22 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light.

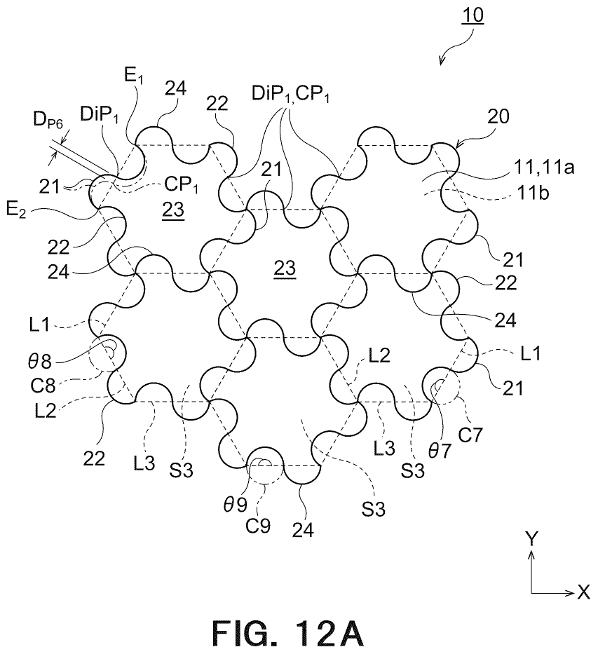

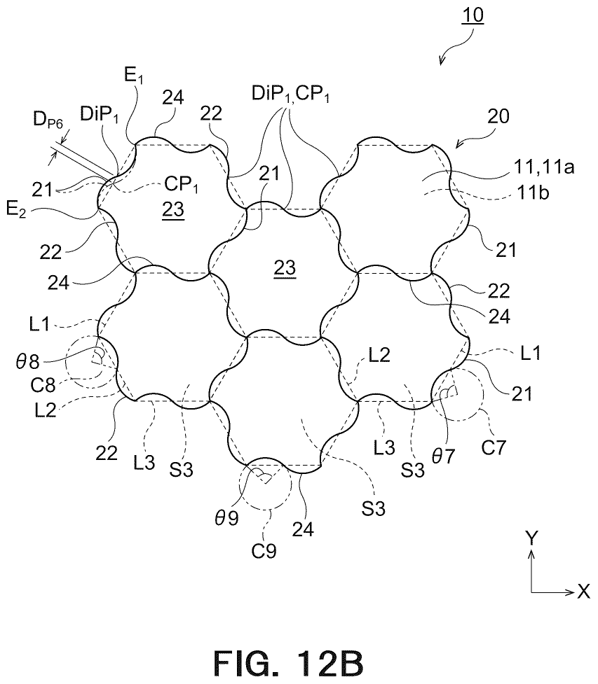

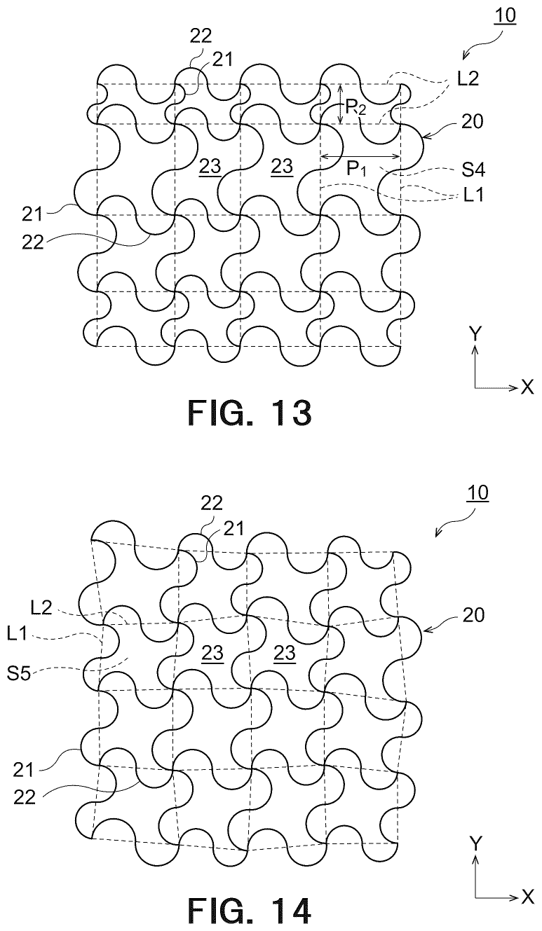

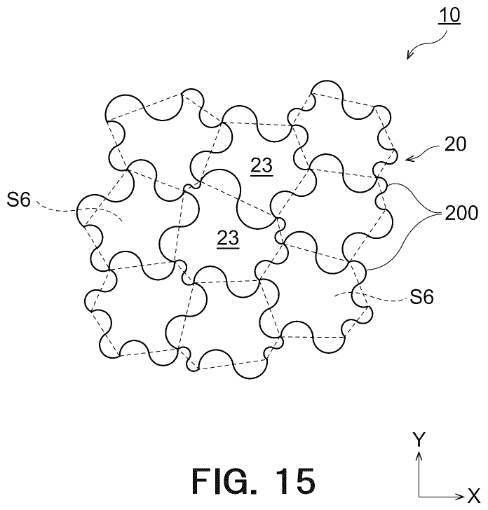

FIG. 12A illustrates a fourth modification to the wiring board 10. The modification illustrated in FIG. 12A differs in that as for the first direction wiring lines 21, the second direction wiring lines 22, and third direction wiring lines 24 that surround the opening portions 23, the shape obtained by connecting the end portions of the chords of the multiple curves is a regular hexagonal shape, and the other components are substantially the same as those according to the embodiment illustrated in FIG. 1 to FIG. 11 described above. In FIG. 12A, components like to those according to the embodiment illustrated in FIG. 1 to FIG. 11 are designated by using like reference signs, and a detailed description is omitted.

As for the wiring board 10 illustrated in FIG. 12A, and the first direction wiring lines 21, the second direction wiring lines 22, and the third direction wiring lines (the wiring lines) 24 that surround the opening portions 23, the shape obtained by connecting the end portions of the chords of the multiple curves is a regular hexagonal shape. In other words, the polygonal shape described above is a regular hexagonal shape. In this case, the first direction wiring lines 21 and the second direction wiring lines 22 extend in directions parallel with neither the X-direction nor the Y-direction. The third direction wiring lines 24 extend in the X-direction. This enables the resistance in the Y-direction in which an electric current flows to be reduced. For this reason, the antenna characteristics can be improved. The third direction wiring lines 24 couple the first direction wiring lines 21 and the second direction wiring lines 22 with each other, and accordingly, the mesh wiring layers 20 can be effectively inhibited from being disconnected. The third direction wiring lines 24 may extend in a direction parallel with neither the X-direction nor the Y-direction. The heights and linewidths of the third direction wiring lines 24 and the materials of the third direction wiring lines 24, for example, may be the same as those of the first direction wiring lines 21.

The first direction wiring lines 21, the second direction wiring lines 22, and the third direction wiring lines 24 have a shape obtained by connecting multiple arcs that are cut at a central angle of 160° or more and 200° or less to each other. In this case, the diameter of a circle from which the arcs are cut may be 0.4 times or more and 0.6 times or less the length of the side of a regular hexagonal shape S3 that is formed by the straight lines L1, the straight lines L2, and straight lines L3. As illustrated by an imaginary line (a two-dot chain line) in FIG. 12A, a minimum distance Dₚ₆ from the first dividing point DiP₁ to the first connection point CP₁ on the side of the regular hexagonal shape S3 that is formed by the straight lines L1, the straight lines L2, and the straight lines L3 may be 0.1 times (N=1) or less the length of the side. Also in the case where the first direction wiring lines 21, the second direction wiring lines 22, and the third direction wiring lines 24 have a shape obtained by connecting arcs that satisfy the relationship described above, substantially perfect circles can be formed by connecting the first direction wiring lines 21, the second direction wiring lines 22, and the third direction wiring lines 24 that surround the opening portions 23. The imaginary line in FIG. 12A is a curve obtained by connecting two arcs to each other when the first connection point CP₁ is not the middle point (the first dividing point DiP₁) of the side.

According to the present modification, as illustrated in FIG. 12A, the first direction wiring lines 21 have a shape obtained by connecting multiple arcs that are cut at a central angle θ7 of 180° to each other. In this case, the diameter of a circle C7 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3. The second direction wiring lines 22 have a shape obtained by connecting multiple arcs that are cut at a central angle θ8 of 180° to each other. In this case, the diameter of a circle C8 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3. The third direction wiring lines 24 have a shape obtained by connecting multiple arcs that are cut at a central angle θ9 of 180° to each other. In this case, the diameter of a circle C9 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3. Also in this case, multiple perfect circles can be formed by connecting the first direction wiring lines 21, the second direction wiring lines 22, and the third direction wiring lines 24 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light.

According to the present modification, as for the first direction wiring lines 21, the second direction wiring lines 22, and the third direction wiring lines 24 that surround the opening portions 23, the shape (the polygonal shape) obtained by connecting the end portions of the chords of the multiple curves is a regular hexagonal shape. In this case, the number of the wiring lines (the first direction wiring lines 21, the second direction wiring lines 22, and the third direction wiring lines 24) that are connected to each of the vertexes of the polygonal shape is 3 at the maximum. Angles that are formed by the first direction wiring lines 21, the second direction wiring lines 22, and the third direction wiring lines 24 at the vertexes of the polygonal shape are 120°, and the angles are larger than those in the case where the polygonal shape is a square shape. For this reason, the patterning precision when the first direction wiring lines 21, the second direction wiring lines 22, and the third direction wiring lines 24 are manufactured and the stability of the dimensions of the first direction wiring lines 21, the second direction wiring lines 22, and the third direction wiring lines 24 can be improved near the vertexes of the polygonal shape. For this reason, the productivity of the wiring board 10 can be improved.

As for the wiring board 10 illustrated in FIG. 12A, an example in which the first direction wiring lines 21, the second direction wiring lines 22, and the third direction wiring lines 24 have a shape obtained by connecting multiple arcs that are cut at a central angle of 160° or more and 200° or less to each other is described, but this is not a limitation. For example, the first direction wiring lines 21, the second direction wiring lines 22, and the third direction wiring lines 24 may have a shape obtained by connecting multiple arcs that are cut at a central angle of 80° or more and 100° or less. Also in this case, the diameter of a circle from which the arcs are cut may be 0.4 times or more and 0.6 times or less the length of the side of the regular hexagonal shape S3 that is formed by the straight lines L1, the straight lines L2, and the straight lines L3. As illustrated by an imaginary line (a two-dot chain line) in FIG. 12B, the minimum distance Dₚ₆ from the first dividing point DiP₁ to the first connection point CP₁ on the side of the regular hexagonal shape S3 that is formed by the straight lines L1, the straight lines L2, and the straight lines L3 may be 0.1 times (N=1) or less the length of the side. The imaginary line in FIG. 12B is a curve obtained by connecting two arcs to each other when the first connection point CP₁ is not the middle point (the first dividing point DiP₁) of the side.

According to the present modification, as illustrated in FIG. 12B, the first direction wiring lines 21 have a shape obtained by connecting multiple arcs that are cut at a central angle θ7 of 90° to each other. Also in this case, the diameter of the circle C7 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3. The second direction wiring lines 22 have a shape obtained by connecting multiple arcs that are cut at a central angle θ8 of 90° to each other. Also in this case, the diameter of the circle C8 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3. The third direction wiring lines 24 have a shape obtained by connecting multiple arcs that are cut at a central angle θ9 of 90° to each other. Also in this case, the diameter of the circle C9 from which the arcs are cut is 0.5 times the length of the side of the regular hexagonal shape S3 that is formed by the straight lines L1, the straight lines L2, and the straight lines L3. The first connection point CP₁ is located on the first dividing point DiP₁ (the middle point of the side) on the side of the regular hexagonal shape S3 that is formed by the straight lines L1, the straight lines L2, and the straight lines L3.

Also in an example illustrated in FIG. 12B, multiple perfect circles can be formed by connecting the first direction wiring lines 21, the second direction wiring lines 22, and the third direction wiring lines 24 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light. Also in the example illustrated in FIG. 12B, the increase rate of the total line length of the first direction wiring lines 21, the second direction wiring lines 22, and the third direction wiring lines 24 with respect to the polygonal shape described above can be reduced, and the resistance value of each mesh wiring layer 20 can be inhibited from increasing. Since the increase rate of the line length described above can be reduced, the aperture ratios of the mesh wiring layers 20 can be inhibited from reducing. Also in the example illustrated in FIG. 12B, since the line length of the first direction wiring lines 21, the line length of the second direction wiring lines 22, and the line length of the third direction wiring lines 24 can be inhibited from being too long, the risk of disconnection of the first direction wiring lines 21, the second direction wiring lines 22, and the third direction wiring lines 24 can be reduced. In addition, the patterning precision when the first direction wiring lines 21, the second direction wiring lines 22, and the third direction wiring lines 24 are manufactured and the stability of the dimensions of the first direction wiring lines 21, the second direction wiring lines 22, and the third direction wiring lines 24 can be improved. For this reason, the productivity of the wiring board 10 can be improved.

FIG. 13 illustrates a fifth modification to the wiring board. The modification illustrated in FIG. 13 differs in that corner portions of the polygonal shape are irregularly arranged, and the other components are substantially the same as those according to the embodiment illustrated in FIG. 1 to FIG. 12B described above. In FIG. 13, components like to those according to the embodiment illustrated in FIG. 1 to FIG. 12B are designated by using like reference signs, and a detailed description is omitted.

As for the wiring board 10 illustrated in FIG. 13, corner portions of a polygonal shape S4 that is formed by the straight lines L1 and the straight lines L2 are irregularly arranged. That is, the straight lines L1 that connect the end portions of the chords of the first direction wiring lines 21 to each other and the straight lines L2 that connect the end portions of the chords of the second direction wiring lines 22 to each other are irregularly arranged. Specifically, the straight lines L1 are parallel with each other, and the pitch P₁ thereof is irregular. Similarly, the straight lines L2 are parallel with each other, and the pitch P₂ thereof is irregular. When the pitch P₁ of the straight lines L1 and the pitch P₂ of the straight lines L2 are irregular, the visibility can be inhibited from reducing due to the beam of light. Also in this case, multiple perfect circles can be formed by connecting the first direction wiring lines 21 and the second direction wiring lines 22 that surround the opening portions 23. Also in this case, many beams of light are superimposed on each other into a circular shape, and consequently, the influence of the beam of light on the visibility can be reduced. For this reason, the visibility can be more effectively inhibited from reducing due to the beam of light.

As illustrated in FIG. 14, a polygonal shape S5 that is formed by the straight lines L1 and the straight lines L2 may be a quadrangular prism shape that has facing sides that are not parallel with each other. In this case, the chords of the curves may extend in a polyline manner. In other words, the chords that are connected to each other may extend in directions that are not parallel with each other. As for mesh wiring lines (wiring lines) 200 that surround the opening portions 23, as illustrated in FIG. 15, the shape obtained by connecting the end portions of the chords of the multiple arcs (the curves) may be a polygonal shape S6, and a planar structure that is formed by the polygonal shape S6 may be a Voronoi pattern. The heights and linewidths of the mesh wiring lines 200 and the materials of the mesh wiring lines 200, for example, may be the same as those of the first direction wiring lines 21.

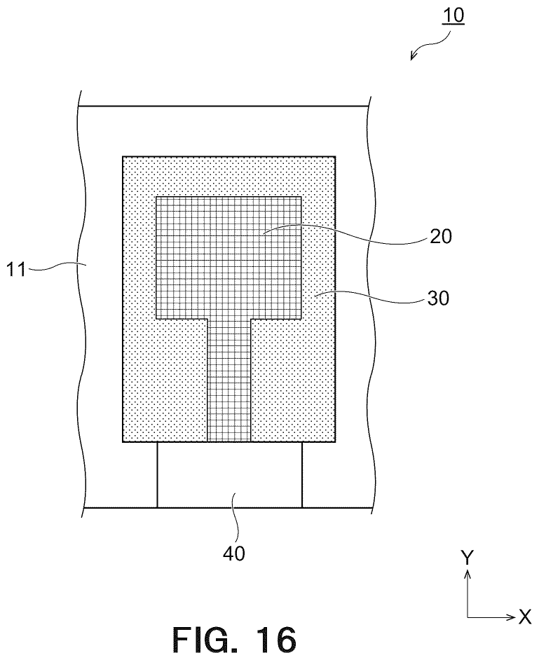

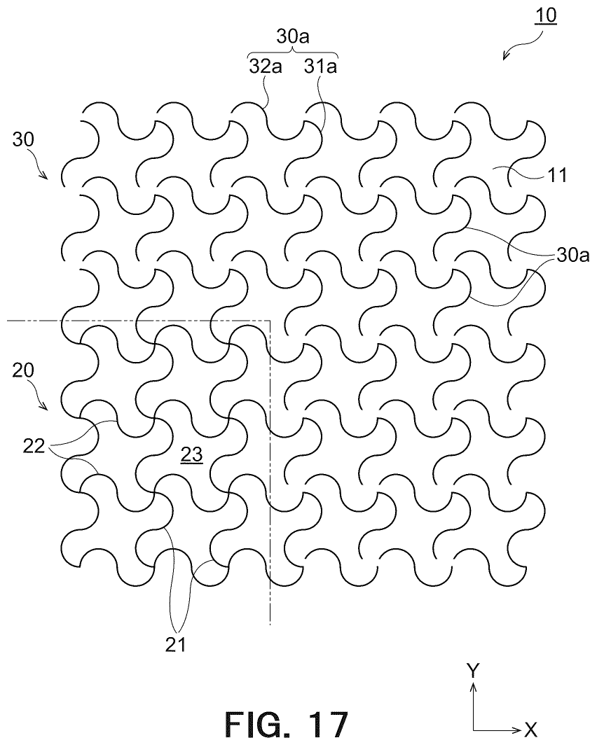

FIG. 16 and FIG. 17 illustrate a sixth modification to the wiring board. The modification illustrated in FIG. 16 and FIG. 17 differs in including dummy wiring layers 30 that are provided around the mesh wiring layers 20, and the other components are substantially the same as those according to the embodiment illustrated in FIG. 1 to FIG. 15 described above. In FIG. 16 and FIG. 17, components like to those according to the embodiment illustrated in FIG. 1 to FIG. 15 are designated by using like reference signs, and a detailed description is omitted.

As for the wiring board 10 illustrated in FIG. 16, the dummy wiring layers 30 are provided around the mesh wiring layers 20. The dummy wiring layers 30 do not function as an antenna substantially unlike the mesh wiring layers 20.

As illustrated in FIG. 17, the dummy wiring layers 30 include dummy wiring lines 30a that have a predetermined pattern and that are repeatedly provided. That is, the dummy wiring layers 30 include the multiple dummy wiring lines 30a, and the dummy wiring lines 30a are electrically separated from the mesh wiring layers 20 (the first direction wiring lines 21 and the second direction wiring lines 22). The multiple dummy wiring lines 30a are regularly arranged over the entire region in the dummy wiring layers 30. The multiple dummy wiring lines 30a are separated from each other in a planar direction and are disposed on the substrate 11 so as to protrude. That is, the dummy wiring lines 30a are electrically separated from the mesh wiring layers 20, the power supply portions 40, and the other dummy wiring lines 30a.

In this case, the shapes of the dummy wiring lines 30a are the same as those obtained by removing portions of the patterns of the mesh wiring layers 20 described above. This enables differences between the mesh wiring layers 20 and the dummy wiring layers 30 to be unlikely to be visually recognized and enables the mesh wiring layers 20 that are disposed on the substrate 11 to be unlikely to be visible. As illustrated in FIG. 17, the dummy wiring lines 30a include first portions 31a obtained by partly cutting the first direction wiring lines 21 and second portions 32a obtained by partly cutting the second direction wiring lines 22. The dummy wiring lines 30a include the portions obtained by partly cutting the first direction wiring lines 21 or the second direction wiring lines 22 as described above, and consequently, the mesh wiring layers 20 that are disposed on the substrate 11 can be more unlikely to be visible. The aperture ratios of the dummy wiring layers 30 may be equal to or may differ from the aperture ratios of the mesh wiring layers 20 but are preferably close to the aperture ratios of the mesh wiring layers 20. For this reason, copper wiring lines that have the same shape as the removed portions may be disposed at freely determined positions in the region of the dummy wiring layers 30 such that the dummy wiring lines 30a are not connected to each other. In this case, the copper wiring lines that have the same area as the removed portions in plan view may be disposed at freely determined positions in the region of the dummy wiring layers 30 such that the dummy wiring lines 30a are not connected to each other.

According to the present modification, the dummy wiring layers 30 that are electrically separated from the mesh wiring layers 20 are provided around the mesh wiring layers 20, and this enables outer edges of the mesh wiring layers 20 to be unclear. This enables the mesh wiring layers 20 to be unlikely to be visible on the front surface of the HMD 90 and enables the mesh wiring layers 20 to be unlikely to be recognized with the naked eye of the user of the HMD 90.

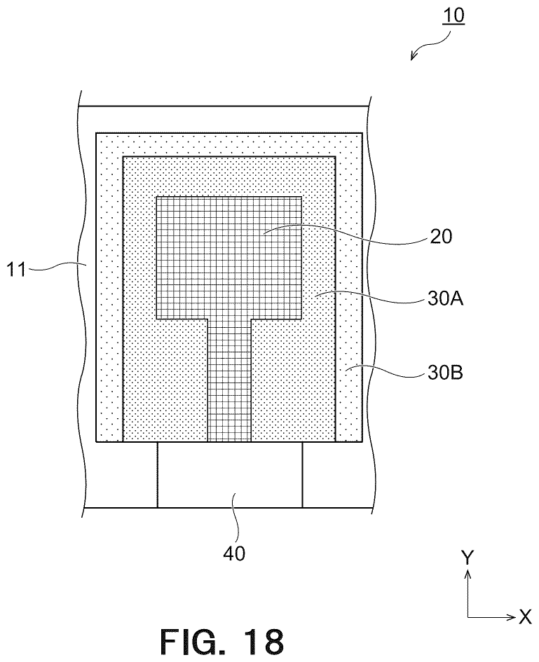

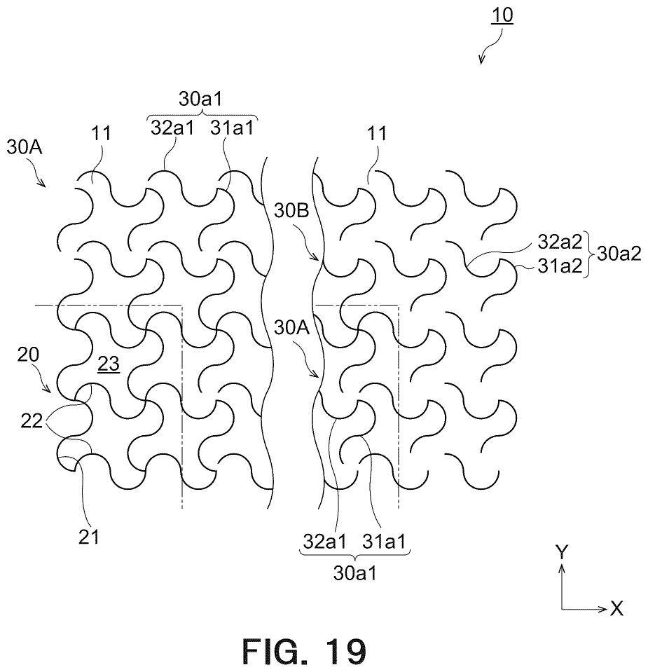

FIG. 18 and FIG. 19 illustrate a seventh modification to the wiring board. The modification illustrated in FIG. 18 and FIG. 19 differs in including multiple dummy wiring layers 30A and 30B that have different aperture ratios and that are provided around the mesh wiring layers 20, and the other components are substantially the same as those according to the embodiment illustrated in FIG. 1 to FIG. 17 described above. In FIG. 18 and FIG. 19, components like to those according to the embodiment illustrated in FIG. 1 to FIG. 17 are designated by using like reference signs, and a detailed description is omitted.

As for the wiring board 10 illustrated in FIG. 18, the multiple (two in this case) dummy wiring layers 30A and 30B (the first dummy wiring layers 30A and the second dummy wiring layers 30B) that have different aperture ratios are provided around the mesh wiring layers 20. Specifically, the first dummy wiring layers 30A are arranged around the mesh wiring layers 20, and the second dummy wiring layers 30B are arranged around the first dummy wiring layers 30A. The dummy wiring layers 30A and 30B do not function as an antenna substantially unlike the mesh wiring layers 20.

As illustrated in FIG. 19, the first dummy wiring layers 30A include dummy wiring lines 30a1 that have a predetermined pattern and that are repeatedly provided. The second dummy wiring layers 30B include dummy wiring lines 30a2 that have a predetermined pattern and that are repeatedly provided. That is, the dummy wiring layers 30A and 30B include the multiple dummy wiring lines 30a1 and 30a2, and the dummy wiring lines 30a1 and 30a2 are electrically separated from the mesh wiring layers 20. The dummy wiring lines 30a1 and 30a2 are regularly arranged over the entire region in the dummy wiring layers 30A and 30B. The dummy wiring lines 30a1 and 30a2 are separated from each other in the planar direction and are disposed on the substrate 11 so as to protrude. The dummy wiring lines 30a1 and 30a2 are electrically separated from the mesh wiring layers 20, the power supply portions 40, and the other dummy wiring lines 30a1 and 30a2.

In this case, the shapes of the dummy wiring lines 30a1 and 30a2 are the same as those obtained by removing portions of the patterns of the mesh wiring layers 20 described above. This enables differences between the mesh wiring layers 20 and the first dummy wiring layers 30A and differences between the first dummy wiring layers 30A and the second dummy wiring layers 30B to be unlikely to be visually recognized and enables the mesh wiring layers 20 that are disposed on the substrate 11 to be unlikely to be visible. As illustrated in FIG. 19, the dummy wiring lines 30a1 include first portions 31a1 that are formed such that the first direction wiring lines 21 are partly cut and second portions 32a1 that are formed such that the second direction wiring lines 22 are partly cut. The dummy wiring lines 30a2 include first portions 31a2 that are formed such that the first direction wiring lines 21 are partly cut and second portions 32a2 that are formed such that the second direction wiring lines 22 are partly cut.

The area of each dummy wiring line 30a1 of the first dummy wiring layers 30A is larger than the area of each dummy wiring line 30a2 of the second dummy wiring layers 30B. In this case, the linewidth of each dummy wiring line 30a1 is equal to the linewidth of each dummy wiring line 30a2 but is not limited thereto, and the linewidth of each dummy wiring line 30a1 may be greater than the linewidth of each dummy wiring line 30a2.

According to the present modification, the aperture ratios of the mesh wiring layers 20 and the multiple dummy wiring layers 30A and 30B preferably increase stepwise in order from the mesh wiring layers 20 to the dummy wiring layers 30A and 30B far from the mesh wiring layers 20. In other words, the aperture ratios of the dummy wiring layers preferably gradually increase in order from a dummy wiring layer close to one of the mesh wiring layers 20 to a dummy wiring layer far therefrom. In this case, the aperture ratios of the first dummy wiring layers 30A are preferably higher than the aperture ratios of the mesh wiring layers 20. The aperture ratios of the second dummy wiring layers 30B are preferably higher than the aperture ratios of the first dummy wiring layers 30A. This enables the outer edges of the mesh wiring layers 20 and outer edges of the dummy wiring layers 30A and 30B to be more unclear. For this reason, the mesh wiring layers 20 can be more unlikely to be visible on the front surface of the HMD 90.

The dummy wiring layers 30A and 30B that are electrically separated from the mesh wiring layers 20 are thus disposed, and consequently, the outer edges of the mesh wiring layers 20 can be more unclear. This enables the mesh wiring layers 20 to be unlikely to be visible on the front surface of the HMD 90 and enables the mesh wiring layers 20 to be unlikely to be recognized with the naked eye of the user of the HMD 90. Three or more dummy wiring layers that have different aperture ratios may be provided around the mesh wiring layers 20.

Multiple components disclosed according to the embodiment and the modifications described above can be appropriately combined as needed. Among all of the components disclosed according to the embodiment and the modifications described above, some of the components may be removed.

The following listing of claims will replace all prior versions, and listings, of claims in the application:

1. A wiring board comprising:
a substrate that is transparent; and
a mesh wiring layer that is disposed on the substrate,
wherein the wiring board has an electromagnetic wave transceiver function,
wherein the mesh wiring layer is configured to be a transceiver portion for an electromagnetic wave and includes a wiring line,
wherein a planar shape of the wiring line has multiple curves that are connected to each other, and
wherein the curves are arcs or elliptical arcs.

2. The wiring board according to claim 1, wherein an aperture ratio of the mesh wiring layer is 94% or more.

3. The wiring board according to claim 1, wherein an opening portion is formed by being surrounded by the wiring line,
wherein as for the wiring line that surrounds the opening portion, a shape obtained by connecting end portions of chords of the multiple curves is a polygonal shape,
wherein the wiring line has a shape obtained by connecting multiple arcs that are cut at a central angle of 160° or more and 200° or less to each other,
wherein a side of the polygonal shape is formed by 2N (N is a natural number of or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

4. The wiring board according to claim 2, wherein an opening portion is formed by being surrounded by the wiring line,
wherein as for the wiring line that surrounds the opening portion, a shape obtained by connecting end portions of chords of the multiple curves is a polygonal shape,
wherein the wiring line has a shape obtained by connecting multiple arcs that are cut at a central angle of 160° or more and 200° or less to each other,
wherein a side of the polygonal shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

5. The wiring board according to claim 3, wherein a plurality of the opening portions is formed, and
wherein a corner portion of the polygonal shape is irregularly arranged.

6. The wiring board according to claim 1, wherein an opening portion is formed by being surrounded by the wiring line,
wherein as for the wiring line that surrounds the opening portion, a shape obtained by connecting end portions of chords of the multiple curves is a square shape,
wherein the wiring line has a shape obtained by connecting multiple arcs that are cut at a central angle of 160° or more and 200° or less to each other,
wherein a side of the square shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

7. The wiring board according to claim 1, wherein an opening portion is formed by being surrounded by the wiring line,
wherein as for the wiring line that surrounds the opening portion, a shape obtained by connecting end portions of chords of the multiple curves is a square shape,
wherein the wiring line has a shape obtained by connecting multiple arcs that are cut at a central angle of 80° or more and 100° or less to each other,
wherein a side of the square shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

8. The wiring board according to claim 1, wherein the curves are arcs that are cut at a central angle of 90° or 180°.

9. The wiring board according to claim 1, wherein an opening portion is formed by being surrounded by the wiring line,
wherein as for the wiring line that surrounds the opening portion, a shape obtained by connecting end portions of chords of the multiple curves is a rhomboidal shape,
wherein the wiring line has a shape obtained by connecting multiple arcs that are cut at a central angle of 160° or more and 200° or less to each other,
wherein a side of the rhomboidal shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

10. The wiring board according to claim 1, wherein an opening portion is formed by being surrounded by the wiring line,
wherein as for the wiring line that surrounds the opening portion, a shape obtained by connecting end portions of chords of the multiple curves is a regular hexagonal shape,
wherein the wiring line has a shape obtained by connecting multiple arcs that are cut at a central angle of 160° or more and 200° or less to each other,
wherein a side of the regular hexagonal shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

11. The wiring board according to claim 1, wherein an opening portion is formed by being surrounded by the wiring line,
wherein as for the wiring line that surrounds the opening portion, a shape obtained by connecting end portions of chords of the multiple curves is a polygonal shape,
wherein the wiring line has a shape obtained by connecting multiple arcs that are cut at a central angle of 80° or more and 100° or less to each other,
wherein a side of the polygonal shape is formed by 2N (N is a natural number of 1 or more) chords, and
wherein a distance from an M-th dividing point to an M-th connection point is 0.1/N times or less a length of the side, where the M-th dividing point is an M-th (M is a natural number of 1 or more and (2N−1) or less) dividing point on the side from one of end portions of the side among dividing points at which the side is equally divided into 2N pieces, and the M-th connection point is an M-th connection point on the side from the one of the end portions of the side among connection points of the chords.

12. The wiring board according to claim 11, wherein the polygonal shape is a rhomboidal shape or a hexagonal shape.

13. The wiring board according to claim 3, wherein N is 1.

14. The wiring board according to claim 1, wherein the wiring board has a radio wave transceiver function at a frequency of 1 GHz or more.

15. The wiring board according to claim 1, wherein the mesh wiring layer has an electromagnetic wave shielding function.

16. The wiring board according to claim 1, wherein an increase in a resistance value of the mesh wiring layer is 10% or less when an operation in which the wiring board is bent at 180° around a cylinder having a diameter of 1 mm and is subsequently stretched is repeated 10 times.

17. The wiring board according to claim 1, wherein a dummy wiring layer that is electrically separated from the mesh wiring layer is provided around the mesh wiring layer.

18. The wiring board according to claim 17, wherein a plurality of the dummy wiring layers is provided, and aperture ratios of the mesh wiring layer and the dummy wiring layers increase stepwise in order from the mesh wiring layer to the dummy wiring layers far from the mesh wiring layer.

19. A head-mounted display comprising:
a frame; and
a display device that is mounted on the frame and that is transparent,
wherein the display device includes:
a first base material;
the wiring board according to claim 1 that is provided on the first base material; and
a display unit that is provided between the first base material and the wiring board.
